(19) United States
(12) Patent Application Publication
(10) Pub. No.: US 2007/0298598 A1
(43) Pub. Date: Dec. 27, 2007

(54) Semiconductor device and method of fabricating semiconductor device

(75) Inventors: Yasuhiro Takeda, Ogaki-shi (JP); Isao Nakano, Hashima-shi (JP); Kazuhiro Kaneda, Ashikaga-shi (JP); Masahiro Oda, Itami-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD., Osaka (JP)

(21) Appl. No.: 11/889,921

(22) Filed: Aug. 17, 2007

Related U.S. Application Data
(62) Division of application No. 10/811,811, filed on Mar. 30, 2004.

(30) Foreign Application Priority Data
Mar. 31, 2003 (JP) JP2003-93420
Mar. 31, 2003 (JP) JP2003-94210
Mar. 31, 2003 (JP) JP2003-93431

(51) Int. Cl. H01L 21/265

(52) U.S. Cl. 438/522; 257/E21.334

(57) ABSTRACT

A semiconductor device capable of improving the operating speed and inhibiting the threshold voltage from fluctuation is obtained. In this semiconductor device, fluorine is introduced into at least any of regions extending over the junction interfaces between a first conductivity type semiconductor region and second conductivity type source/drain regions, at least the interface between the gate insulator film and the central region of a channel region as well as a gate insulator film, and side wall insulator films.

### BACKGROUND OF THE INVENTION

1. Field of the Invention

The present invention relates to a semiconductor device and a method of fabricating a semiconductor device, and more particularly, it relates to a semiconductor device having a metal-insulator semiconductor field-effect transistor (MIS-FET) and a method of fabricating a semiconductor device.

2. Description of the Background Art

In recent years, a MOS field-effect transistor or the like has been scaled down following high integration of a semiconductor device. When a MOS field-effect transistor is refined according to a scaling rule, the impurity concentration in a semiconductor substrate is increased to suppress the short channel effect that leads to increase parasitic capacitances in p-n junctions of source/drain regions of the MOS field-effect transistor formed in the semiconductor substrate. When the parasitic capacitances are increased, the operating speed of the MOS field-effect transistor is disadvantageously reduced. Therefore, it is extremely important to reduce the parasitic capacitances in order to increase the speed of a semiconductor integrated circuit.

In general, a method of reducing parasitic capacitances of p-n junctions by implanting an impurity of the same conductivity type as that in the semiconductor substrate into portions close to the p-n junctions is proposed in Japanese Patent Laying-Open No. 5-102477 (1993), for example.

According to Japanese Patent Laying-Open No. 5-102477, a first conductivity type impurity identical to that in a first conductivity type semiconductor substrate is implanted through a mask of a gate electrode for forming first conductivity type low-concentration impurity regions around lower portions of high-concentration impurity regions constituting second conductivity type source/drain regions. Thus, the difference between impurity concentrations around the p-n junction interfaces of the high-concentration impurity regions of the second conductivity type source/drain regions is so reduced as to reduce parasitic capacitances. The operating speed of a semiconductor device can be improved due to the reduction of the parasitic capacitances. In recent years, however, the thickness of a gate electrode of a MOS field-effect transistor has been extremely reduced following reduction of the transistor size. When the gate electrode is employed as a mask for implanting a first conductivity type impurity as in the aforementioned Japanese Patent Laying-Open No. 5-102477, therefore, the first conductivity type impurity is disadvantageously implanted through the gate electrode into a first conductivity type channel region located under the gate electrode. Consequently, the impurity concentration in the channel region fluctuates to disadvantageously result in fluctuation of the threshold voltage of the transistor.

In recent years, further, a MOS field-effect transistor or the like has been increasingly refined following high integration of a semiconductor device. When a MOS field-effect transistor is refined, the distance between a gate electrode and source/drain regions is reduced due to reduction of the thickness of a gate insulator film. Thus, parasitic capacitances (overlap capacitances) caused through insulator films formed between the gate electrode and the source/drain regions are increased. When the overlap capacitances are increased, the operating speed of the MOS field-effect transistor is disadvantageously reduced. Therefore, it is extremely important to reduce the overlap capacitances in order to increase the speed of a semiconductor integrated circuit. In general, therefore, Japanese Patent Laying-Open No. 2000-323710 proposes a method of forming both ends of a gate insulator film by low dielectric constant oxide films containing fluorine implanted therein in order to reduce overlap capacitances between a gate electrode and source/drain regions. In this conventional method of fabricating a semiconductor device, however, regions formed with the low dielectric constant oxide films are so small that it is difficult to sufficiently reduce the overlap capacitances between the gate electrode and the source/drain regions. Therefore, it is disadvantageously difficult to improve the operating speed by reducing the overlap capacitances.

When a MOS field-effect transistor is used over a long period, fluctuation of the threshold voltage is disadvantageously remarkably increased due to dangling bonds of silicon atoms formed in a gate insulator film and on the interface between the gate insulator film and a silicon substrate in general. In order to eliminate this disadvantage, Japanese Patent Laying-Open No. 2001-156291 proposes a technique of thermally diffusing fluorine implanted into the surfaces of source/drain regions into a channel region thereby terminating dangling bonds in the channel region with fluorine. According to this technique, however, fluorine ions are insufficiently diffused into the central region of the channel region if the channel length (gate length) is large, and hence dangling bonds are not terminated with fluorine on the interface between the gate insulator film and the central region of the channel region. Consequently, fluctuation of the threshold voltage is disadvantageously remarkably increased due to dangling bonds on the central region of the channel region.

### SUMMARY OF THE INVENTION

An object of the present invention is to provide a semiconductor device capable of improving the operating speed and inhibiting the threshold voltage from fluctuation.

Another object of the present invention is to provide a method of fabricating a semiconductor device capable of improving the operating speed and inhibiting the threshold voltage from fluctuation.

In order to attain the aforementioned objects, a semiconductor device according to a first aspect of the present invention comprises a first conductivity type semiconductor region having a main surface, second conductivity type source/drain regions formed on the main surface of the semiconductor region to hold a channel region therebetween at a prescribed interval, a gate electrode formed on the channel region through a gate insulator film and side wall insulator films formed on the side surfaces of the gate electrode. Fluorine is introduced into at least any of regions extending over the junction interfaces between the first conductivity type semiconductor region and the second conductivity type source/drain regions, at least the interface between the gate insulator film and the central region of the channel region as well as the gate insulator film, and the side wall insulator films.

In the semiconductor device according to the first aspect, as hereinabove described, fluorine is introduced into at least any of the regions extending over the junction interfaces between the first conductivity type semiconductor region and the second conductivity type source/drain regions, at least the interface between the gate insulator film and the central region of the channel region as well as the gate insulator film and the side wall insulator films so that the junction capacitances (p-n junction capacitances) between the semiconductor region and the source/drain regions can be reduced with fluorine when fluorine is introduced into the regions extending over the junction interfaces between the first conductivity type semiconductor region and the second conductivity type source/drain regions, for example, whereby the operating speed of the semiconductor device can be improved. Also when fluorine introduced into the junction interfaces reaches the channel region, this fluorine, serving as neither donor nor acceptor, exerts no influence on the concentration of a first conductivity type impurity in the channel region. Thus, the threshold voltage can be inhibited from fluctuation resulting from fluctuation of the impurity concentration in the channel region. When fluorine is introduced into at least the interface between the gate insulator film and the central region of the channel region and the gate insulator film, dangling bonds in at least the central region of the channel region and the gate insulator film can be terminated with this fluorine. Thus, fluctuation of the threshold voltage can be inhibited from increase resulting from dangling bonds in the interface between the gate insulator film and the central region of the channel region when the sizes of dangling bonds in the gate insulator film and the gate length (channel length) are large. Also in this case, the threshold voltage can be inhibited from fluctuation. When fluorine is introduced into the side wall insulator films, the dielectric constant of the side wall insulator films can be so sufficiently reduced as to sufficiently reduce the dielectric constant of insulator films provided between the gate electrode and the source/drain regions. Consequently, the overlap capacitances between the gate electrode and the source/drain regions can be so sufficiently reduced as to improve the operating speed of the semiconductor device.

In the aforementioned semiconductor device according to the first aspect, fluorine is preferably introduced into the regions extending over the junction interfaces between the first conductivity type semiconductor region and the second conductivity type source/drain regions, at least the interface between the gate insulator film and the central region of the channel region as well as the gate insulator film, and the side wall insulator films. According to this structure, reduction of the parasitic capacitances of the source/drain regions without varying the threshold voltage that result from fluctuation of the impurity concentration in the channel region, suppression of fluctuation of the threshold voltage resulting from dangling bonds in the interface between the gate insulator film and the central region of the channel region and reduction of the overlap capacitances between the gate electrode and the source/drain regions can be attained at the same time. Thus, the operating speed of the semiconductor device can be further improved and the threshold voltage can be further inhibited from fluctuation.

In the aforementioned semiconductor device according to the first aspect, the first conductivity type semiconductor region may include a first conductivity type silicon region. According to this structure, dangling bonds of silicon can be easily terminated with fluorine while the junction capacitances on the p-n junction interfaces of the source/drain regions (silicon region) can be easily reduced with fluorine.

In the aforementioned semiconductor device according to the first aspect, the side wall insulator films may consist of insulator films containing Si. According to this structure, the dielectric constant of the side wall insulator films can be easily reduced by introducing fluorine into the side wall insulator films consisting of the insulator films containing Si.

A semiconductor device according to a second aspect of the present invention comprises a first conductivity type semiconductor region having a main surface and a second conductivity type impurity region formed on the main surface of the semiconductor region. An element of at least either fluorine or carbon is introduced into a region extending over the junction interface between the first conductivity type semiconductor region and the second conductivity type impurity region.

In the semiconductor device according to the second aspect, as hereinabove described, the element of at least either fluorine or carbon is introduced into the region extending over the junction interface between the first conductivity type semiconductor region and the second conductivity type impurity region so that the capacitance (p-n junction capacitance) on the junction interface between the first conductivity type semiconductor region and the second conductivity type impurity region can be reduced, whereby the operating speed of the semiconductor device can be improved. Also when fluorine introduced into the junction interface reaches a channel region, this fluorine, serving as neither donor nor acceptor, exerts no influence on the impurity concentration in the first conductivity type semiconductor region constituting the channel region. Thus, the threshold voltage can be inhibited from fluctuation resulting from fluctuation of the impurity concentration in the channel region.

In the aforementioned semiconductor device according to the second aspect, the impurity region preferably includes a low-concentration impurity region and a high-concentration impurity region, and the element of at least either fluorine or carbon is preferably introduced into at least a region extending over the junction interface between the first conductivity type semiconductor region and the high-concentration impurity region. According to this structure, fluorine or carbon can be introduced into the region extending over the junction interface between the semiconductor region and the high-concentration impurity region having a large junction capacitance, whereby the junction capacitance between the semiconductor region and the impurity region can be efficiently reduced. Thus, the operating speed of the semiconductor device can be easily improved.

The aforementioned semiconductor device according to the second aspect preferably further comprises a gate electrode formed on the main surface of the semiconductor region through a gate insulator film and side wall insulator films formed on the side surfaces of the gate electrode, and the element of at least either fluorine or carbon is preferably introduced also into the side wall insulator films. According to this structure, the dielectric constant of the side wall insulator films can be so reduced that the overlap capacitances between the gate electrode and source/drain regions can also be reduced in addition to reduction of the junction capacitance between the semiconductor region and the impurity region. Thus, the operating speed of the semiconductor device can be further improved.

In the aforementioned semiconductor device according to the second aspect, the impurity region preferably includes second conductivity type source/drain regions formed on the main surface of the semiconductor region to hold a channel region therebetween at a prescribed interval, the element of at least either fluorine or carbon is preferably fluorine, and this fluorine is preferably introduced also into at least the interface between the gate insulator film and the central region of the channel region as well as the gate insulator film. According to this structure, dangling bonds in at least the interface between the gate insulator film and the central region of the channel region and the gate insulator film can be terminated with this fluorine, whereby fluctuation of the threshold voltage can be reduced resulting from dangling bonds in the interface between the gate insulator film and the central region of the channel region when the sizes of dangling bonds in the gate insulator film and the gate length (channel length) are large. Thus, the threshold voltage can be inhibited not only from fluctuation resulting from fluctuation of the impurity concentration in the channel region but also from fluctuation resulting from dangling bonds in the central region of the channel region.

A semiconductor device according to a third aspect of the present invention comprises a first conductivity type semiconductor region having a main surface, second conductivity type source/drain regions formed on the main surface of the semiconductor region to hold a channel region therebetween at a prescribed interval, a gate electrode formed on the channel region through a gate insulator film and side wall insulator films formed on the side surfaces of the gate electrode. An element reducing the dielectric constant is introduced into the side wall insulator films.

In the semiconductor device according to the third aspect, the element reducing the dielectric constant is so introduced into the side wall insulator films that the dielectric constant of the side wall insulator films can be sufficiently reduced, whereby the dielectric constant of insulator films provided between the gate electrode and the source/drain regions can be sufficiently reduced. Consequently, the overlap capacitances between the gate electrode and the source/drain regions can be so sufficiently reduced as to improve the operating speed of the semiconductor device.

In the aforementioned semiconductor device according to the third aspect, the element reducing the dielectric constant may include an element of at least either fluorine or carbon, and the side wall insulator films may consist of insulator films containing Si. According to this structure, the dielectric constant of the side wall insulator films can be easily reduced by introducing the element of at least either fluorine or carbon into the side wall insulator films consisting of the insulator films containing Si.

In the semiconductor device according to the third aspect including the aforementioned element of at least either fluorine or carbon as the element reducing the dielectric constant, the element of at least either fluorine or carbon is introduced also into regions extending over the junction interfaces between the first conductivity type semiconductor region and the second conductivity type source/drain regions. According to this structure, the capacitances (p-n junction capacitances) on the junction interfaces between the first conductivity type semiconductor region and the second conductivity type source/drain regions can be so reduced as to further improve the operating speed of the semiconductor device. Also when the element of at least either fluorine or carbon introduced into the junction interfaces reaches the channel region, this fluorine or carbon, serving as neither donor nor acceptor, exerts no influence on the impurity concentration in the first conductivity type semiconductor region constituting the channel region. Thus, the threshold voltage can be inhibited from variation resulting from fluctuation of the impurity concentration in the channel region.

A semiconductor device according to a fourth aspect of the present invention comprises a first conductivity type semiconductor region having a main surface, second conductivity type source/drain regions formed on the main surface of the semiconductor region to hold a channel region therebetween at a prescribed interval and a gate electrode formed on the channel region through a gate insulator film. A halogenic element is introduced into at least the interface between the gate insulator film and the central region of the channel region and the gate insulator film.

In the semiconductor device according to the fourth aspect, as hereinabove described, the halogenic element is introduced into at least the central region of the channel region and insulator film so that dangling bonds in the gate insulator film and at least the central region of the channel region can be terminated with this halogenic element. Thus, fluctuation of the threshold voltage can be inhibited from increase resulting from dangling bonds in the central region of the channel region when the sizes of dangling bonds in the gate insulator film and the gate length (channel length) are large.

In the aforementioned semiconductor device according to the fourth aspect, the halogenic element may be fluorine, and the first conductivity type semiconductor region may include a first conductivity type silicon region. According to this structure, dangling bonds in the gate insulator film and those of silicon in the channel region can be easily terminated with fluorine.

The semiconductor device according to the fourth aspect employing the aforementioned halogenic element of fluorine preferably further comprises side wall insulator films formed on the side surfaces of the gate electrode, and the fluorine is preferably introduced also into the side wall insulator films. According to this structure, the dielectric constant of the side wall insulator films can be so sufficiently reduced as to sufficiently reduce the dielectric constant of insulator films provided between the gate electrode and the source/drain regions. Consequently, the threshold voltage can be inhibited from fluctuation resulting from dangling bonds in the gate insulator film and the channel region while the operating speed of the semiconductor device can be improved by reducing the overlap capacitances.

In the semiconductor device according to the fourth aspect employing the aforementioned halogenic element of fluorine, the fluorine is preferably introduced also into regions extending over the junction interfaces between the first conductivity type semiconductor region and the second conductivity type source/drain regions. According to this structure, the capacitances (p-n junction capacitances) on the junction interfaces between the first conductivity-type semiconductor region and the second conductivity type source/drain regions can also be reduced, whereby the operating speed of the semiconductor device can be further improved. Also when fluorine introduced into the junction interfaces reaches the channel region, this fluorine, serving as neither donor nor acceptor, exerts no influence on the impurity concentration in the first conductivity type semiconductor region constituting the channel region. Thus, the threshold voltage can be inhibited from variation resulting from fluctuation of the impurity concentration in the channel region. Consequently, the threshold voltage can be inhibited not only from fluctuation resulting from dangling bonds in the gate insulator film and the central region of the channel region but also from fluctuation resulting from fluctuation of the impurity concentration in the channel region.

A method of fabricating a semiconductor device according to a fifth aspect of the present invention comprises steps of forming second conductivity type source/drain regions on the main surface of a first conductivity type semiconductor region to hold a channel region therebetween at a prescribed interval, forming a gate electrode on the channel region through a gate insulator film, forming side wall insulator films on the side surfaces of the gate electrode and introducing fluorine into at least any of regions extending over the junction interfaces between the first conductivity type semiconductor region and the second conductivity type source/drain regions, at least the central region of the channel region as well as the gate insulator film, and the side wall insulator films.

In the method of fabricating a semiconductor device according to the fifth aspect, as hereinabove described, fluorine is introduced into at least any of the regions extending over the junction interfaces between the first conductivity type semiconductor region and the second conductivity type source/drain regions, at least the central region of the channel region as well as the gate insulator film and the side wall insulator films so that the junction capacitances (p-n junction capacitances) between the semiconductor region and the source/drain regions can be reduced with fluorine when fluorine is introduced into the regions extending over the junction interfaces between the first conductivity type semiconductor region and the second conductivity type source/drain regions, for example, whereby the operating speed of the semiconductor device can be improved. Also when fluorine introduced into the junction interfaces reaches the channel region, this fluorine, serving as neither donor nor acceptor, exerts no influence on the concentration of a first conductivity type impurity in the channel region. Thus, the threshold voltage can be inhibited from variation resulting from fluctuation of the impurity concentration in the channel region. When fluorine is introduced into at least the central region of the channel region and the gate insulator film, dangling bonds in the gate insulator film and at least the central region of the channel region can be terminated with this fluorine. Thus, fluctuation of the threshold voltage can be reduced. When fluorine is introduced into the side wall insulator films, the dielectric constant of the side wall insulator films can be so sufficiently reduced as to sufficiently reduce the dielectric constant of insulator films provided between the gate electrode and the source/drain regions. Consequently, the overlap capacitances between the gate electrode and the source/drain regions can be so sufficiently reduced as to improve the operating speed of the semiconductor device.

In the aforementioned method of fabricating a semiconductor device according to the fifth aspect, the step of introducing fluorine preferably includes a step of ion-implanting the fluorine into the gate electrode and thereafter performing heat treatment thereby diffusing the fluorine from the gate electrode into the side wall insulator films while diffusing the fluorine from the gate electrode into the gate insulator film and at least the central region of the channel region. According to this structure, fluorine can be easily introduced into the side wall insulator films, the gate insulator film and at least the central region of the channel region.

In the aforementioned method of fabricating a semiconductor device according to the fifth aspect, the step of introducing fluorine preferably includes a step of ion-implanting the fluorine into the regions extending over the junction interfaces between the first conductivity type semiconductor region and the second conductivity type source/drain regions. According to this structure, fluorine can be easily introduced into the regions extending over the junction interfaces between the first conductivity type semiconductor region and the second conductivity type source/drain regions.

A method of fabricating a semiconductor device according to a sixth aspect of the present invention comprises steps of forming a second conductivity type impurity region on the main surface of a first conductivity type semiconductor region and introducing an element of at least either fluorine or carbon into a region extending over the junction interface between the second conductivity type impurity region and the first conductivity type semiconductor region.

In the method of fabricating a semiconductor device according to the sixth aspect, as hereinabove described, the element of at least either fluorine or carbon is introduced into the region extending over the junction interface between the second conductivity type impurity region and the first conductivity type semiconductor region so that the junction capacitance (p-n junction capacitance) between the semiconductor region and the impurity region can be reduced with fluorine or carbon, whereby the operating speed of the semiconductor device can be improved. Also when fluorine or carbon introduced into the junction interface reaches a channel region, this fluorine or carbon, serving as neither donor nor acceptor, exerts no influence on the impurity concentration in the first conductivity type semiconductor region constituting the channel region. Thus, the threshold voltage can be inhibited from variation resulting from fluctuation of the impurity concentration in the channel region.

In the aforementioned method of fabricating a semiconductor device according to the sixth aspect, the step of forming the second conductivity type impurity region preferably includes a step of forming a second conductivity type source/drain region including a low-concentration impurity region and a high-concentration impurity region, and the step of introducing the element of at least either fluorine or carbon preferably includes a step of introducing the element of at least either fluorine or carbon into at least a region extending over the junction interface between the first conductivity type semiconductor region and the high-concentration impurity region. According to this structure, at least either fluorine or carbon can be introduced into the region extending over the junction interface between the semiconductor region and the high-concentration impurity region having a large junction capacitance, whereby the junction capacitance between the semiconductor region and the source/drain region can be effectively reduced. Thus, the operating speed of the semiconductor device can be easily improved.

In the aforementioned method of fabricating a semiconductor device according to the sixth aspect, the step of introducing the element of at least either fluorine or carbon preferably includes a step of ion-implanting fluorine into the region extending over the junction interface between the second conductivity type impurity region and the first conductivity type semiconductor region at an implantation dosage of at least about 1.5×10¹⁵ cm⁻² and not more than about 3×10¹⁵ cm⁻². When fluorine is ion-implanted at this implantation dosage, the junction capacitance on the junction interface between the second conductivity type impurity region and the first conductivity type semiconductor region can be easily reduced.

A method of fabricating a semiconductor device according to a seventh aspect of the present invention comprises steps of forming a gate electrode on the surface of a first conductivity type semiconductor region through a gate insulator film, ion-implanting an element reducing the dielectric constant at least into the gate electrode, forming side wall insulator films on the side surfaces of the gate electrode, forming a silicon nitride film at least on the side wall insulator films and diffusing the element reducing the dielectric constant from the gate electrode into the side wall insulator films by heat treatment.

In the method of fabricating a semiconductor device according to the seventh aspect, as hereinabove described, the element reducing the dielectric constant is diffused from the gate electrode into the side wall insulator films by the heat treatment so that the dielectric constant of the side wall insulator films can be sufficiently reduced, whereby the dielectric constant of insulator films provided between the gate electrode and source/drain regions can be sufficiently reduced. Consequently, the overlap capacitances between the gate electrode and the source/drain regions can be so sufficiently reduced as to improve the operating speed of the semiconductor device. Further, the silicon nitride film is formed at least on the side wall insulator films prior to heat treatment, whereby the element reducing the dielectric constant can be inhibited from outward diffusion with the silicon nitride film in the heat treatment.

In the aforementioned method of fabricating a semiconductor device according to the seventh aspect, the step of ion-implanting the element reducing the dielectric constant preferably includes a step of implanting the element reducing the dielectric constant also into the first conductivity type semiconductor region, and the step of diffusing the element reducing the dielectric constant from the gate electrode into the side wall insulator films preferably includes a step of diffusing the element reducing the dielectric constant from the first conductivity type semiconductor region into the side wall insulator films by heat treatment. According to this structure, the element reducing the dielectric constant can be diffused into the side wall insulator films in a larger quantity, thereby further sufficiently reducing the dielectric constant of the side wall insulator films. Consequently, the operating speed of the semiconductor device can be further improved.

A method of fabricating a semiconductor device according to an eight aspect of the present invention comprises steps of forming a gate electrode on the main surface of a silicon substrate through a gate insulator film, ion-implanting a halogenic element into the gate electrode and diffusing the halogenic element in the gate electrode into the gate insulator film and the interface between the gate insulator film and the silicon substrate by heat-treating the silicon substrate.

In the method of fabricating a semiconductor device according to the eighth aspect, as hereinabove described, the silicon substrate is so heat-treated as to diffuse the halogenic element from the gate electrode into the gate insulator film and the interface between the gate insulator film and the silicon substrate, whereby the halogenic element can be easily diffused from the gate electrode into the gate insulator film and the overall channel region located on the interface between the gate insulator film and the silicon substrate. Thus, dangling bonds in the gate insulator film and the overall channel region including the central region thereof can be terminated with the halogenic element, whereby fluctuation of the threshold voltage can be inhibited from increase resulting from dangling bonds in the central region of the channel region also when the gate length (channel length) is large.

In the aforementioned method of fabricating a semiconductor device according to the eighth aspect, the halogenic element may be fluorine. According to this structure, dangling bonds in the gate insulator film and the interface between the gate insulator film and the silicon substrate can be easily terminated with fluorine.

In the aforementioned method of fabricating a semiconductor device according to the eighth aspect, the step of ion-implanting the halogenic element may include a step of ion-implanting the fluorine at an implantation dosage of at least about 1.5×10¹⁵ cm⁻² and not more than about 5×10¹⁵ cm⁻². When fluorine is ion-implanted at this implantation dosage, the halogenic element can be easily introduced into the gate electrode to be easily diffused from the gate electrode into the gate insulator film and the interface between the gate insulator film and the silicon substrate.

In the aforementioned method of fabricating a semiconductor device according to the eighth aspect, the heat treatment for diffusing the halogenic element is preferably performed only once after ion implantation of the halogenic element. According to this structure, the heat treatment step may be carried out only once, whereby the fabrication process can be simplified.

A method of fabricating a semiconductor device according to a ninth aspect of the present invention comprises steps of forming a gate electrode on the main surface of a first conductivity type silicon substrate through a gate insulator film, forming a pair of second conductivity type source/drain regions on the main surface of the silicon substrate to hold a channel region therebetween, ion-implanting a halogenic element into the source/drain regions and the gate electrode and diffusing the halogenic element in the gate electrode into the gate insulator film and the channel region located on the interface between the gate insulator film and the silicon substrate while diffusing the halogenic element in the source/drain regions into the channel region located under the gate insulator film by heat-treating the silicon substrate.

In the method of fabricating a semiconductor device according to the ninth aspect, as hereinabove described, the silicon substrate is so heat-treated as to diffuse the halogenic element in the gate electrode into the gate insulator film and the interface between the gate insulator film and the silicon substrate while diffusing the halogenic element in the source/drain regions into the channel region located under the gate insulator film, whereby the halogenic element can be diffused into the gate insulator film while a larger quantity of the halogenic element can be diffused into the overall channel region including the central region thereof. Thus, a larger quantity of dangling bonds present in the gate insulator film and the interface between the gate insulator and the overall channel region can be terminated with the halogenic element. Consequently, the threshold voltage can be further inhibited from remarkable fluctuation resulting from dangling bonds in the interface between the gate insulator film and the central region of the channel region when the sizes of dangling bonds in the gate insulator film and the gate length (channel length) are large.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a semiconductor device according to a first embodiment of the present invention;

FIG. 2 is a correlation diagram showing the relation between the implantation dosage for fluorine ions implanted into a portion close to a p-n junction and a parasitic capacitance caused in the vicinity of the p-n junction;

FIGS. 3 to 11 are sectional views for illustrating a process of fabricating the semiconductor device according to the first embodiment of the present invention shown in FIG. 1;

FIG. 12 is a correlation diagram showing the relation between the implantation rate for fluorine ions implanted into a portion close to a p-n junction and the threshold voltage of a p-channel MOS field-effect transistor;

FIG. 13 is a sectional view showing a semiconductor device according to a second embodiment of the present invention;

FIGS. 14 to 26 are sectional views for illustrating a process of fabricating the semiconductor device according to the second embodiment of the present invention shown in FIG. 13;

FIG. 27 is a sectional view showing a semiconductor device according to a third embodiment of the present invention;

FIG. 28 is an enlarged view showing a portion around a MOS field-effect transistor in the semiconductor device according to the third embodiment of the present invention shown in FIG. 27;

FIG. 29 is a correlation diagram showing the relation between peripheral lengths of gate electrodes and overlap capacitances caused between the gate electrodes and sources/drains in cases of implanting and not implanting fluorine ions respectively;

FIGS. 30 to 43 are sectional views for illustrating a process of fabricating the semiconductor device according to the third embodiment of the present invention shown in FIG. 27;

FIG. 44 is a sectional view showing a semiconductor device according to a fourth embodiment of the present invention;

FIGS. 45 to 52 are sectional views for illustrating a process of fabricating the semiconductor device according to the fourth embodiment of the present invention shown in FIG. 44;

FIG. 53 is a correlation diagram showing the relation between the dosages of fluorine ions and NBTI lifetime of a PMOSFET; and

FIG. 54 is a correlation diagram showing the relation between a voltage application time and change of a threshold voltage.

### DESCRIPTION OF THE PREFERRED EMBODIMENTS

Embodiments of the present invention are now described with reference to the drawings.

### First Embodiment

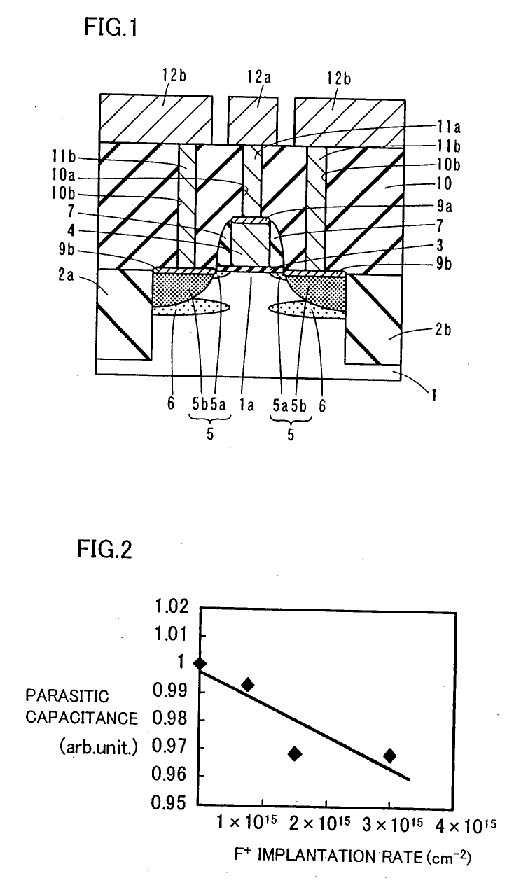

The structure of a semiconductor device (p-channel MOS field-effect transistor) according to a first embodiment of the present invention is described with reference to FIG. 1.

In the semiconductor device according to the first embodiment, element isolation regions 2a and 2b having an STI (shallow trench isolation) are formed on prescribed regions of the main surface of an n-type single-crystalline silicon substrate 1 for isolating an element forming region (active region) from adjacent ones, as shown in FIG. 1. The n-type single-crystalline silicon substrate 1 is an example of the “first conductivity type semiconductor region” in the present invention. A pair of p-type source/drain regions 5 are formed on the element forming region held between the element isolation regions 2a and 2b to hold a channel region 1a. Each of the source/drain regions 5 of the p-channel MOS field-effect transistor has an LDD (lightly doped drain) structure consisting of a low-concentration impurity region 5a and a high-concentration impurity region 5b. The source/drain regions 5 are examples of the “impurity region” in the present invention. A gate electrode 4 consisting of a polycrystalline silicon layer having a thickness of about 150 nm to about 200 nm is formed on the channel region 1a through a gate insulator film 3 of SiO₂ having a thickness of about 2 nm to about 10 nm. The pair of p-type source/drain regions 5, the gate insulator film 3 and the gate electrode 4 constitute the p-channel MOS field-effect transistor.

According to the first embodiment, fluoric regions 6 containing fluorine are formed to extend over the junction interfaces between the high-concentration impurity regions 5b constituting the source/drain regions 5 and the n-type single-crystalline silicon substrate 1. The fluoric regions 6 are formed in parallel with the main surface of the n-type single-crystalline silicon substrate 1 to extend at least toward portions located under the low-concentration impurity regions 5a constituting the source/drain regions 5.

Side wall insulator films 7 of silicon oxide are formed on the side surfaces of the gate electrode 4. Silicide films 9a and 9b of CoSi₂ are formed on the upper surfaces of the gate electrode 4 and the high-concentration impurity regions 5b constituting the source/drain regions 5 respectively.

An interlayer dielectric film 10 of silicon oxide having a thickness of about 1000 nm is formed to cover the overall surface. This interlayer dielectric film 10 has contact holes 10a and 10b reaching the silicide films 9a and 9b respectively. Plugs 11a and 11b of tungsten are embedded in the contact holes 10a and 10b respectively. Wires 12a and 12b are formed to be connected with the plugs 11a and 11b respectively. The wires 12a and 12b consist of Ti layers having a thickness of about 30 nm, TiN layers having a thickness of about 30 nm and AlCu layers having a thickness of about 400 nm in ascending order.

In the semiconductor device according to the first embodiment, as hereinabove described, the fluoric regions 6 containing fluorine are provided around the lower portions (p-n junctions) of the high-concentration impurity regions 5b constituting the p-type source/drain regions 5 so that the dielectric constant of the silicon substrate 1 is reduced in the vicinity of the fluoric regions 6 as compared with that in the active region of the n-type single-crystalline silicon substrate 1.

In general, a parasitic capacitance Cd caused in the vicinity of a p-n junction is expressed as follows:

$$Cd = \frac{{ɛ}_{0} {ɛ}_{ s}}{Xd} \qquad ( 1 )$$

where ε₀ and εₛ represent the dielectric constants of a vacuum and silicon respectively, and Xd represents the width of a depletion layer of the p-n junction. The width Xd of the depletion layer is expressed as follows:

$$Xd = \sqrt{\frac{2 {ɛ}_{0} {ɛ}_{ s}}{qNB} ( Vbi + Vbs )} \qquad ( 2 )$$

where q represents the elementary charge quantity, NB represents the substrate impurity concentration around the depletion layer, Vbi represents the built-in potential and Vbs represents the substrate bias voltage (source-to-substrate voltage) respectively. The following expression (3) is derived from the above expressions (1) and (2):

$$Cd = \sqrt{{ɛ}_{s}} \cdot \frac{\sqrt{{ɛ}_{0}}}{\sqrt{\frac{2}{qNB} ( Vbi + Vbs )}} \qquad ( 3 )$$

It is understood from the above expression (3) that the parasitic capacitance Cd caused in the vicinity of the p-n junction is proportionate to the square root of the dielectric constant εₛ of the silicon substrate. In other words, the dielectric constant εₛ of the silicon substrate is reduced when fluorine is ion-implanted into a portion around the p-n junction, whereby the parasitic capacitance Cd caused on the p-n junction can be reduced. While the parasitic capacitance Cd depends on the substrate concentration NB in the vicinity of the depletion layer in the above expression (3), fluorine ions serve as neither donors nor acceptors, and hence change of the substrate concentration NB resulting from ion implantation of fluorine may not be taken into consideration.

FIG. 2 shows data of values actually measured by varying the implantation rate for fluorine ions (F⁺) implanted into the portion around the p-n junction. As understood from FIG. 2, the parasitic capacitance of the p-n junction can be reduced by about 3% when ion-implanting fluorine at an implantation dosage of 1.5×10¹⁵ cm⁻² to 3×10¹⁵ cm⁻².

In the semiconductor device according to the first embodiment, as hereinabove described, the fluoric regions 6 containing fluorine ions are provided around the lower portions (p-n junctions) of the high-concentration impurity regions 5b constituting the source/drain regions 5 so that the dielectric constant of the fluoric regions 6 is reduced, whereby the parasitic capacitances can be reduced.

A process of fabricating the semiconductor device (p-channel MOS field-effect transistor) according to the first embodiment is described with reference to FIGS. 1 and 3 to 11.

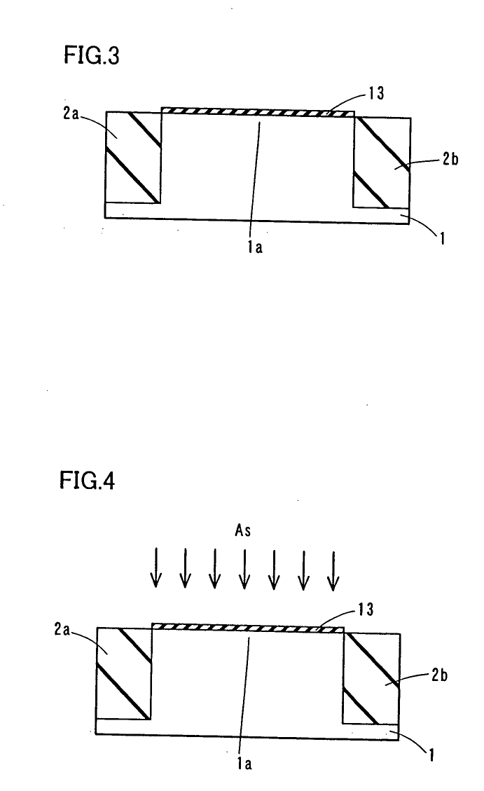

As shown in FIG. 3, the element isolation regions 2a and 2b having the STI structure are formed on the prescribed regions of the main surface of the n-type single-crystalline silicon substrate 1 for isolating the active region. Thereafter the surface of the n-type single-crystalline silicon substrate 1 is oxidized thereby forming a sacrifice oxide film 13 consisting of silicon oxide.

As shown in FIG. 4, arsenic (As) is ion-implanted into the n-type single-crystalline substrate 1 through the aforementioned sacrifice oxide film 13 at implantation ion energy of about 100 keV to about 140 keV and an implantation dosage of about 0.5×10¹² cm⁻² to about 1×10¹³ cm⁻². Thus, the impurity concentration in the channel region la is adjusted for optimizing the threshold voltage. Thereafter the sacrifice oxide film 13 is removed.

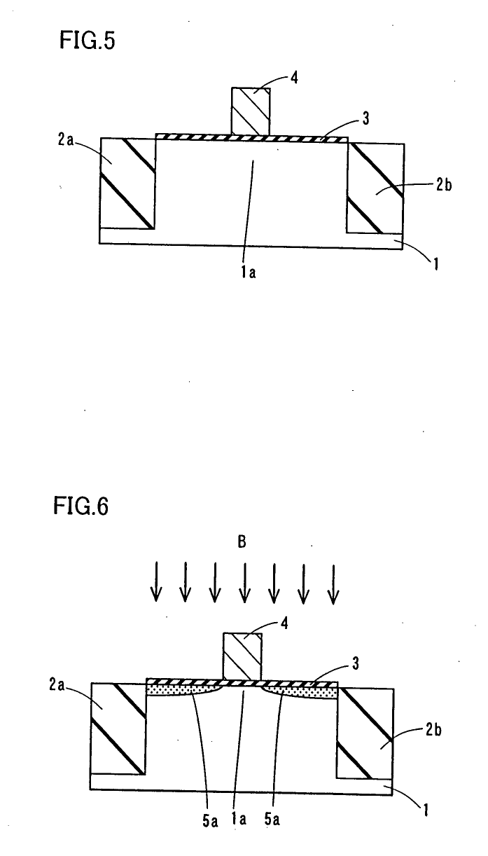

As shown in FIG. 5, thermal oxidation is performed at about 800° C. to about 900° C., thereby forming the gate insulator film 3 of silicon dioxide having the thickness of about 2 nm to about 10 nm on the surface of the n-type single-crystalline silicon substrate 1. Thereafter a polycrystalline silicon film (not shown) is deposited on the overall surface by CVD with a thickness of about 150 nm to about 200 nm and thereafter patterned by general photolithography and RIE (reactive ion etching), thereby forming the gate electrode 4 of polycrystalline silicon. The gate insulator film 3, remarkably damaged by the aforementioned etching, is reoxidized after formation of the gate electrode 4.

As shown in FIG. 6, the gate electrode 4 is employed as a mask for ion-implanting boron (B) serving as a p-type impurity at implantation energy of about 5 keV to about 10 keV and an implantation rate of about 1×10¹³ cm⁻² to about 5×10¹⁴ cm⁻², thereby forming the p-type low-concentration impurity regions 5a to hold the channel region la therebetween.

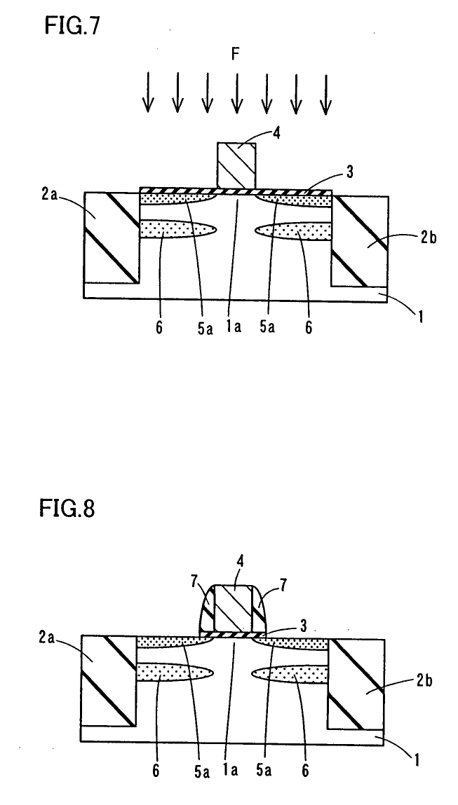

As shown in FIG. 7, fluorine (F) is ion-implanted into the overall surface at implantation energy of about 20 keV and an implantation rate of about 3×10¹⁵ cm⁻², thereby forming the fluoric regions 6 containing fluorine.

An insulator film (not shown) of silicon oxide or the like is deposited on the overall surface by CVD and thereafter etched back by RIE, thereby forming the side wall insulator films 7 on the side surfaces of the gate electrode 4 as shown in FIG. 8. In the aforementioned etch-back step, portions of the gate insulator film 3 excluding regions located immediately under the gate electrode 4 and the side wall insulator films 7 are removed.

As shown in FIG. 9, a silicon nitride film 8 having a thickness of about 5 nm to about 20 nm is deposited on the overall surface, in order to prevent channeling in a later ion implantation step for forming the high-concentration impurity regions 5b constituting the source/drain regions 5.

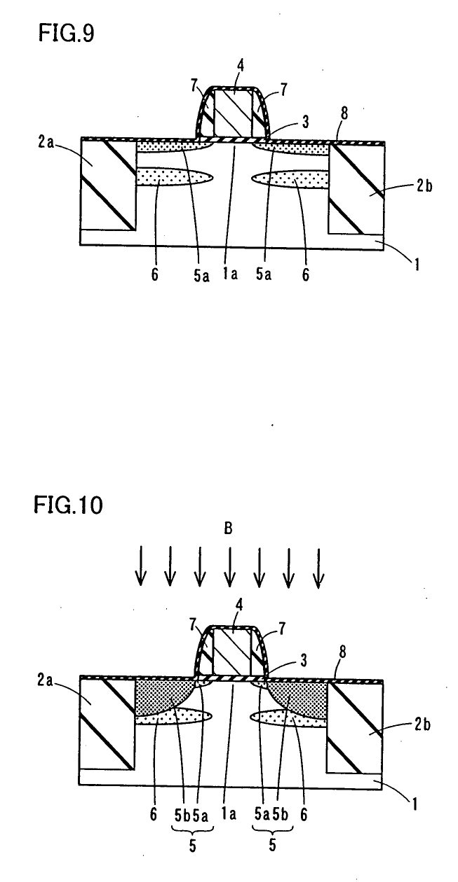

As shown in FIG. 10, boron (B) is ion-implanted into the n-type single-crystalline silicon substrate 1 through the silicon nitride film 8 at implantation energy of about 5 keV to about 10 keV and an implantation rate of about 1×10¹⁵ cm⁻² to about 5×10¹⁵ cm⁻², thereby forming the p-type high-concentration impurity regions 5b. At this time, the fluoric regions 6 containing fluorine are positioned on regions extending over the junction interfaces between the p-type high-concentration impurity regions 5b and the n-type single-crystalline silicon substrate 1.

Thereafter heat treatment is performed by RTA (rapid thermal annealing) at about 700° C. to about 1100° C. for about 0.1 seconds to about 60 seconds, thereby activating the impurity (B) implanted into the p-type high-concentration impurity regions 5b.

When the fluoric regions 6 do not extend over the junction interfaces between the p-type high-concentration impurity regions 5b and the n-type single-crystalline silicon substrate 1 upon formation of the p-type high-concentration impurity regions 5b through the aforementioned step of ion-implanting boron, the p-type high-concentration impurity regions 5b and the fluoric regions 6 are so diffused through the step of activating boron by RTA that the fluoric regions 6 extend over the junction interfaces between the p-type high-concentration impurity regions 5b and the n-type single-crystalline silicon substrate 1.

The aforementioned p-type low-concentration impurity regions 5a and the p-type high-concentration impurity regions 5b form the pair of p-type source/drain regions 5 having the LDD structure. Thereafter the silicon nitride film 8 is removed.

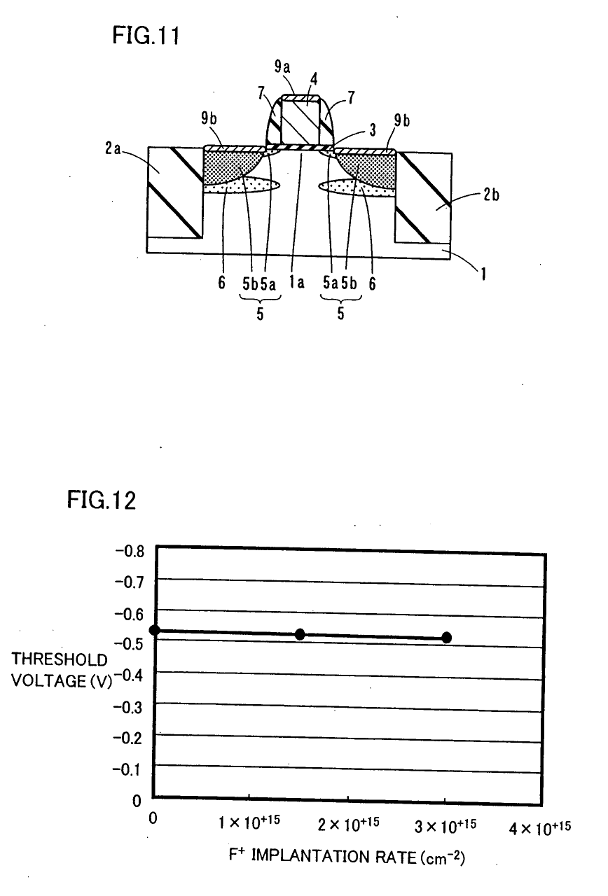

As shown in FIG. 11, the silicide films 9a and 9b of cobalt silicide (CoSi₂) are formed on the upper surfaces of the gate electrode 4 of polycrystalline silicon and the p-type high-concentration impurity regions 5b constituting the source/drain regions 5 respectively in a self-aligned manner through a salicide (self-aligned silicide) process.

Thereafter the interlayer dielectric film 10 is formed by CVD and the contact holes 10a and 10b are formed on the prescribed regions by photolithography and dry etching such as RIE, as shown in FIG. 1. Tungsten is embedded in the contact holes 10a and 10b by CVD, thereby forming the plugs 11a and 11b respectively. Finally, a multilayer film (not shown) consisting of a Ti layer having a thickness o about 30 nm, a TiN layer having a thickness of about 30 nm and an AlCu layer having a thickness of about 400 nm in ascending order is formed on the upper surface of the interlayer dielectric film 10 and thereafter patterned, thereby forming the upper wires 12a and 12b. The p-channel MOS field-effect transistor (semiconductor device) according to the first embodiment is formed in the aforementioned manner.

According to the first embodiment, as hereinabove described, the fluoric regions 6 containing fluorine are so provided as to extend over the junction interfaces between the p-type high-concentration impurity regions 5b constituting the p-type source/drain regions 5 and the n-type single-crystalline silicon substrate 1, whereby the parasitic capacitances can be reduced around the lower portions (p-n junctions) of the high-concentration impurity regions 5b. Thus, the operating speed of the semiconductor device (p-channel MOS field-effect transistor) can be improved.

According to the first embodiment, further, ion implantation is employed for introducing fluorine, so that fluorine can be precisely introduced into prescribed regions of the n-type single-crystalline silicon substrate 1. Thus, the parasitic capacitances on the p-n junctions of the source/drain regions 5 can be reduced without dispersion.

FIG. 12 shows actually measured data indicating fluctuation of the threshold voltage of a p-channel MOS field-effect transistor in a case of varying an implantation rate for implanting fluorine ions (F⁺) into a portion around a p-n junction. Under this measurement condition, fluorine reaches a channel region. In general, the allowance for threshold voltage fluctuation is about ±50 mV in consideration of an error of the implantation rate for ion implantation performed for regulating the threshold voltage and dispersion of the thickness of a gate insulator film. It is understood from FIG. 12 that fluctuation of the threshold voltage is not more than 3.5 mW when fluorine ions are implanted at an implantation dosage of about 1.5×10¹⁵ cm⁻² to about 3×10¹⁵ cm⁻², and it is obvious that fluctuation of the threshold voltage resulting from implantation of fluorine ions substantially causes no problem.

According to the first embodiment, therefore, fluctuation of the threshold voltage of the p-channel MOS field-effect transistor causes no problem also when fluorine ion-implanted through the mask of the gate electrode 4 reaches the channel region 1a located under the gate electrode 4 due to the small thickness of the gate electrode 4.

According to the first embodiment, as hereinabove described, the operating speed can be improved by reducing the parasitic capacitances of the p-n junctions of the source/drain regions 5 while inhibiting the threshold voltage of the p-channel MOS field-effect transistor from fluctuation.

### Second Embodiment

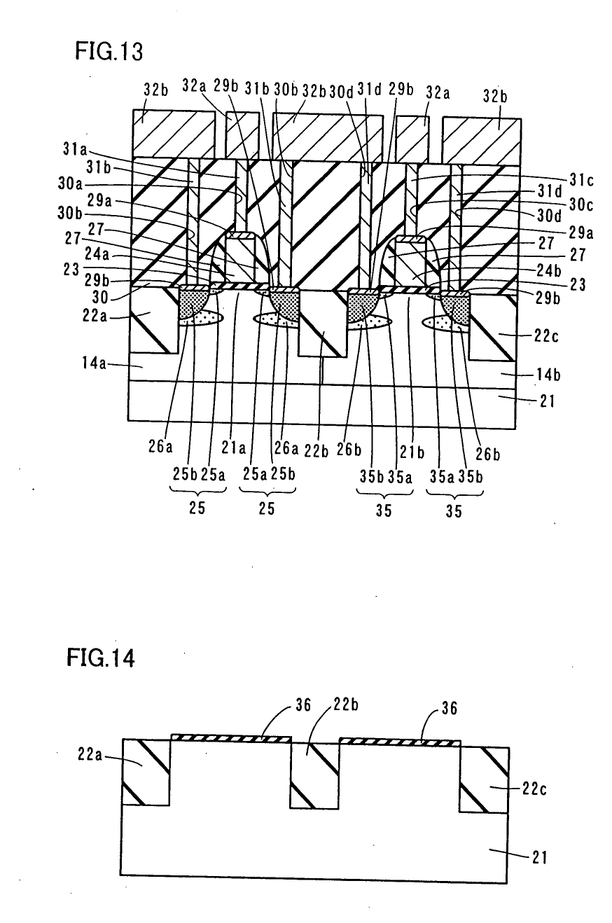

Referring to FIG. 13, the present invention is applied to a CMOS inverter having complementarily functioning n- and p-channel MOS field-effect transistors in a semiconductor device according to a second embodiment of the present invention.

In the semiconductor device according to the second embodiment, element isolation regions 22a, 22b and 22c having an STI structure are formed on prescribed regions of the main surface of a p-type single-crystalline silicon substrate 21 for isolating an element forming region (active region) from adjacent ones, as shown in FIG. 13. A p well region 14a and an n well region 14b are formed on regions of the p-type single-crystalline substrate 21 formed with n- and p-channel MOS field-effect transistors respectively. The p and n well regions 14a and 14b are examples of the “semiconductor region” in the present invention. A pair of n-type source/drain regions 25 are formed in the p well region 14a to hold a channel region 21a. Each of the n-type source/drain regions 25 has an LDD structure consisting of an n-type low-concentration impurity region 25a and an n-type high-concentration impurity region 25b. The n-type source/drain regions 25 are examples of the “impurity region” in the present invention. A gate electrode 24a of polycrystalline silicon having a thickness of about 150 nm to about 200 nm is formed on the channel region 21a through a gate insulator film 23 of silicon oxynitride having a thickness of about 2 nm to about 10 nm. The pair of n-type source/drain regions 25, the gate insulator film 23 and the gate electrode 24a constitute the n-channel MOS field-effect transistor.

A pair of p-type source/drain regions 35 are formed in the n well region 14b to hold a channel region 21b. Each of the p-type source/drain regions 35 has an LDD structure consisting of a p-type low-concentration impurity region 35a and a p-type high-concentration impurity region 35b. The p-type source/drain regions 35 are examples of the “impurity region” in the present invention. A gate electrode 24b of polycrystalline silicon having a thickness of about 150 nm to about 200 nm is formed on the channel region 21b through a gate insulator film 23 of silicon oxynitride having a thickness of about 2 nm to about 10 nm. The pair of p-type source/drain regions 35, the gate insulator film 23 and the gate electrode 24b constitute the p-channel MOS field-effect transistor.

According to the second embodiment, fluoric regions 26a and 26b containing fluorine are formed around the lower portions (p-n junctions) of the high-concentration impurity regions 25b and 35b constituting the source/drain regions 25 and 35 of the n- and p-channel MOS field-effect transistors respectively. In other words, the fluoric regions 26a and 26b are formed to extend over the junction interfaces between the n- and p-type high-concentration impurity regions 25b and 35b and the p and n well regions 14a and 14b respectively. The fluoric regions 26a and 26b are formed to extend in parallel with the main surface of the p-type single-crystalline silicon substrate 21 at least toward portions located under the low-concentration impurity regions 25a and 35a constituting the source/drain regions 25 and 35 respectively.

Side wall insulator films 27 of silicon oxide or the like are formed on the side surfaces of the gate electrodes 24a and 24b constituting the n- and p-channel MOS field-effect transistors respectively. Silicide films 29a and 29b of CoSi₂ are formed on the upper surfaces of the gate electrodes 24a and 24b and the high-concentration impurity regions 25b and 35b constituting the source/drain regions 25 and 35 respectively.

An interlayer dielectric film 30 of silicon oxide having a thickness of about 1000 nm is formed to cover the overall surface. This interlayer dielectric film 30 has contact holes 30a, 30b, 30c and 30d reaching the silicide films 29a and 29b respectively. Plugs 31a, 31b, 31c and 31d of tungsten are embedded in the contact holes 30a, 30b, 30c and 30d respectively. Wires 32a and 32b are formed to be connected with the plugs 31a, 31b, 31c and 31d respectively. The wires 32a and 32b consist of Ti layers having a thickness of about 30 nm, TiN layers having a thickness of about 30 nm and AlCu layers having a thickness of about 400 nm in ascending order.

The n- and p-type source/drain regions 25 and 35 of the aforementioned n- and p-type MOS field-effect transistors are connected with each other through the plugs 31b and 31d and the upper wires 32b. The gate electrodes 24a and 24b of the n- and p-channel MOS field-effect transistors are connected with each other through the plugs 31a and 31c, the upper wires 32a and wires (not shown) located on higher layers. Thus, the CMOS inverter is constituted.

In the semiconductor device according to the second embodiment, as hereinabove described, the fluoric regions 26a and 26b containing fluorine are provided to extend over the p-n junction interfaces between the high-concentration impurity regions 25b and 35b constituting the source/drain regions 25 and 35 of the n- and p-channel MOS field-effect transistors respectively, whereby the dielectric constant in portions around the fluoric regions 26a and 26b is reduced as compared with that in the p and n well regions 14a and 14b. Thus, both of the parasitic capacitances on the p-n junction interfaces of the n- and p-type source/drain regions 25 and 35 of the n- and p-channel MOS field-effect transistors can be reduced. Therefore, the operating speed of the semiconductor device (CMOS inverter) can be improved.

A process of fabricating the semiconductor device (CMOS inverter) according to the second embodiment is described with reference to FIGS. 13 to 26.

As shown in FIG. 14, the element isolation regions 22a, 22b and 22c having the STI structure are formed on the prescribed regions of the main surface of the p-type single-crystalline silicon substrate 21 for isolating the active region from the adjacent ones. Thereafter the surface of the p-type single-crystalline silicon substrate 21 is oxidized, thereby forming a sacrifice oxide film 36 of silicon oxide.

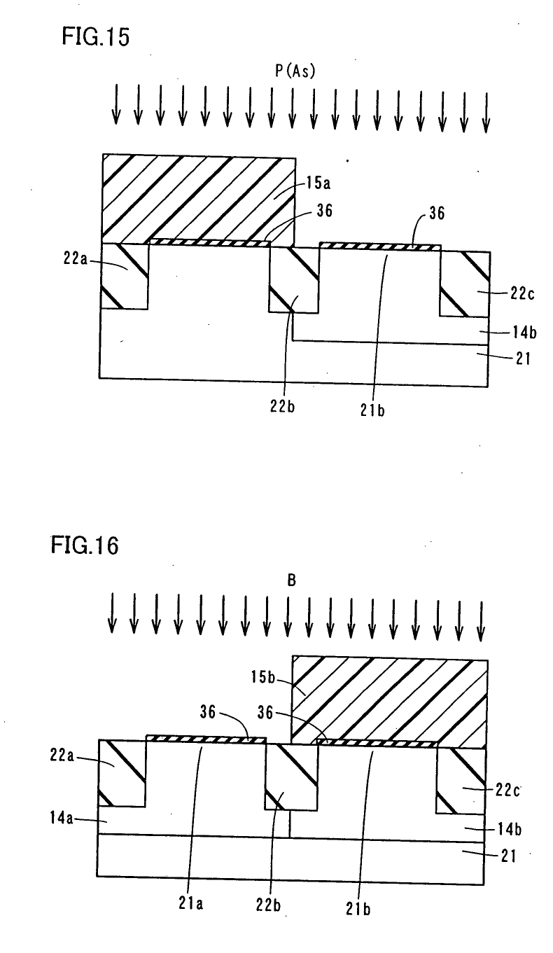

As shown in FIG. 15, a resist film 15a is formed by lithography to cover the region to be formed with the n-channel MOS field-effect transistor. Thereafter the resist film 15a is employed as a mask for ion-implanting phosphorus (P) into the p-type single-crystalline silicon substrate 21 through the aforementioned sacrifice oxide film 36 at implantation energy of about 380 keV and an implantation dosage of about 4×10¹³ cm⁻², thereby forming the n well region 14b. Further, arsenic (As) is ion-implanted at implantation energy of about 100 keV to about 140 keV and an implantation dosage of about 0.5×10¹² cm⁻² to about 1×10¹³ cm⁻² for adjusting the impurity concentration in the channel region 21b, thereby optimizing the threshold voltage. Thereafter the resist film 15a is removed.

As shown in FIG. 16, another resist film 15b is formed by lithography to cover the region to be formed with the p-channel MOS field-effect transistor. Boron (B) is ion-implanted into the p-type single-crystalline silicon substrate 21 through the aforementioned sacrifice oxide film 36 at implantation energy of about 190 keV and an implantation rate of about 4×10¹³ cm⁻², thereby forming the p well region 14a. Further, boron (B) is ion-implanted at implantation energy of about 10 keV to about 30 keV and an implantation dosage of about 1×10¹² cm⁻² to about 1×10¹³ cm⁻² for adjusting the impurity concentration in the channel region 21a, thereby optimizing the threshold voltage. Thereafter the resist film 15b is removed.

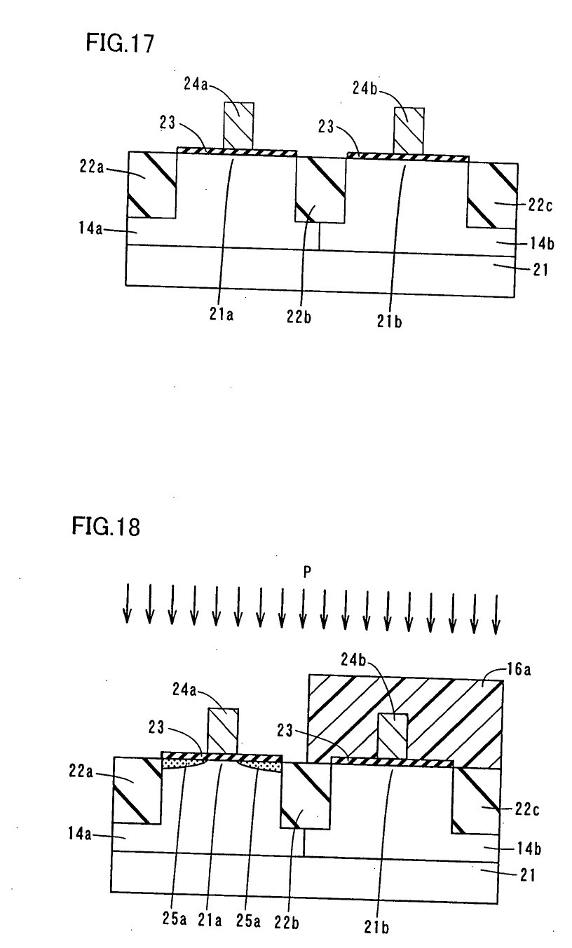

As shown in FIG. 17, a silicon dioxide film is formed on the surface of the p-type single-crystalline silicon substrate 21 by heat treatment in an oxidizing atmosphere with a thickness of about 2 nm to about 10 nm and thereafter annealed in an NO atmosphere, thereby forming the gate insulator film 23 of silicon oxynitride having the thickness of about 2 nm to about 10 nm on the surface of the p-type single-crystalline silicon substrate 21. Thereafter a polycrystalline silicon film (not shown) is deposited on the overall surface by CVD with a thickness of about 150 nm to about 200 nm, and thereafter patterned by general photolithography and etching by RIE, thereby forming the gate electrodes 24a and 24b of polycrystalline silicon. The gate insulator film 23, remarkably damaged by the aforementioned etching, is reoxidized after formation of the gate electrodes 24a and 24b.

As shown in FIG. 18, still another resist film 16a is formed to cover the region to be formed with the p-channel MOS field-effect transistor. Thereafter phosphorus (P) is ion-implanted into the main surface of the p well region 14a at implantation energy of about 30 keV, an implantation dosage of about 0.5×10¹³ cm⁻² to about 5×10¹⁴ cm⁻² and an incidence angle of about 7° four times while rotating the p-type single-crystalline silicon substrate 21 by 90°. Thus, the n-type low-concentration impurity regions 25a are formed to constitute the source/drain regions 25 of the n-channel MOS field-effect transistor. Thereafter the resist film 16a is removed.

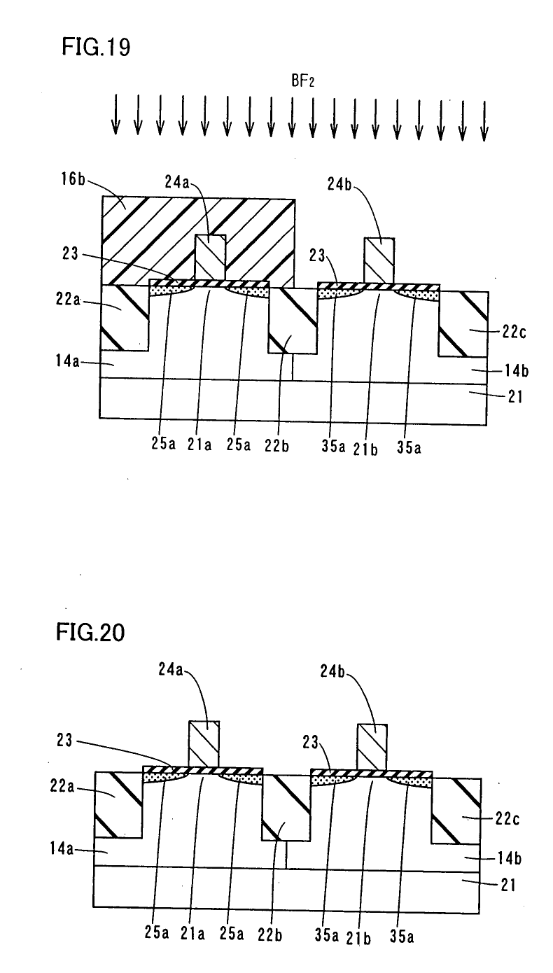

As shown in FIG. 19, a further resist film 16b is formed to cover the region to be formed with the n-channel MOS field-effect transistor. Thereafter boron difluoride (BF₂) is ion-implanted into the main surface of the n well region 14b at implantation energy of about 15 keV, an implantation dosage of about 1×10¹³ cm⁻² to about 5×10¹⁴ cm⁻² and an incidence angle of about 7° four times while rotating the p-type single-crystalline silicon substrate 21 by 90°. Thus, the p-type low-concentration impurity regions 35a are formed to constitute the source/drain regions 35 of the p-channel MOS field-effect transistor. Thereafter the resist film 16b is removed, as shown in FIG. 20.

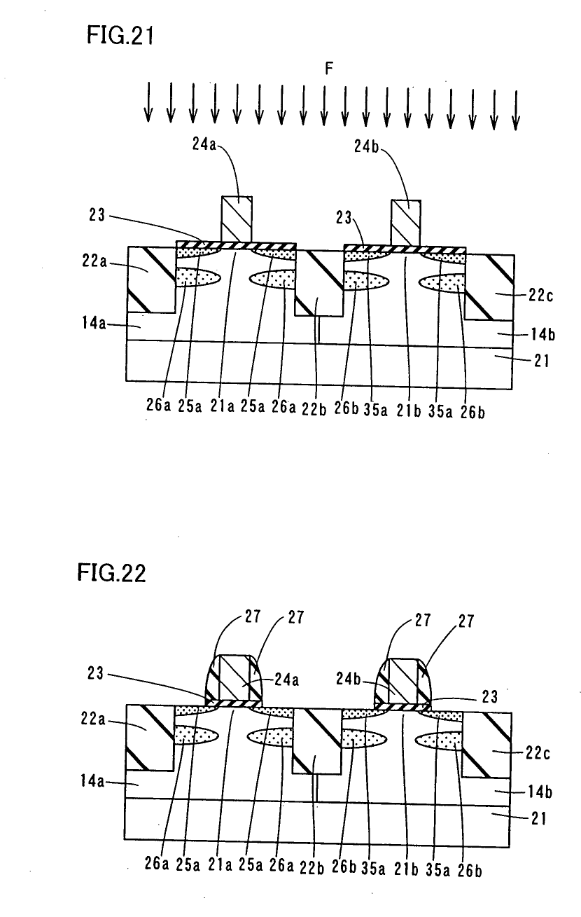

As shown in FIG. 21, fluorine (F) is ion-implanted into the overall surface at implantation energy of about 20 keV and an implantation dosage of about 3×10¹⁵ cm⁻². Thus, the fluoric regions 26a and 26b containing fluorine are formed in the p and n well regions 14a and 14b respectively.

An insulator film (not shown) of silicon oxide or the like is deposited on the overall surface by CVD and thereafter etched back by RIE, thereby forming the side wall insulator films 27 on the side surfaces of the gate electrodes 24a and 24b as shown in FIG. 22. In the aforementioned etch-back step, portions of the gate insulator films 23 excluding regions located immediately under the gate electrodes 24a and 24b and the side wall insulator films 27 are removed.

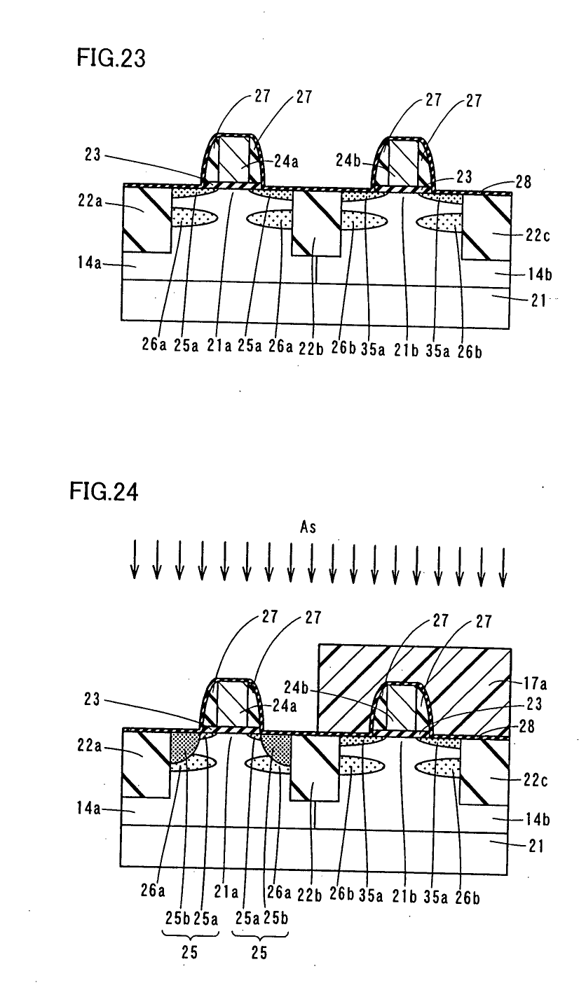

As shown in FIG. 23, a silicon nitride film 28 having a thickness of about 5 nm to about 20 nm is deposited on the overall surface. This silicon nitride film 28 also has a function of preventing channeling in a later ion implantation step, similarly to that in the first embodiment.

As shown in FIG. 24, a resist film 17a is formed to cover the region to be formed with the p-channel MOS field-effect transistor. Thereafter arsenic (As) is ion-implanted into the p-type single-crystalline silicon substrate 21 at implantation energy of about 45 keV and an implantation dosage of about 1×10¹⁵ cm⁻² to about 5×10¹⁵ cm⁻², thereby forming the n-type high-concentration impurity regions 25b constituting the source/drain regions 25 of the n-channel MOS field-effect transistor. At this time, the fluoric regions 26a containing fluorine extend over the junction interfaces between the n-type high-concentration impurity regions 25b and the p well region 14a. Thereafter the resist film 17a is removed.

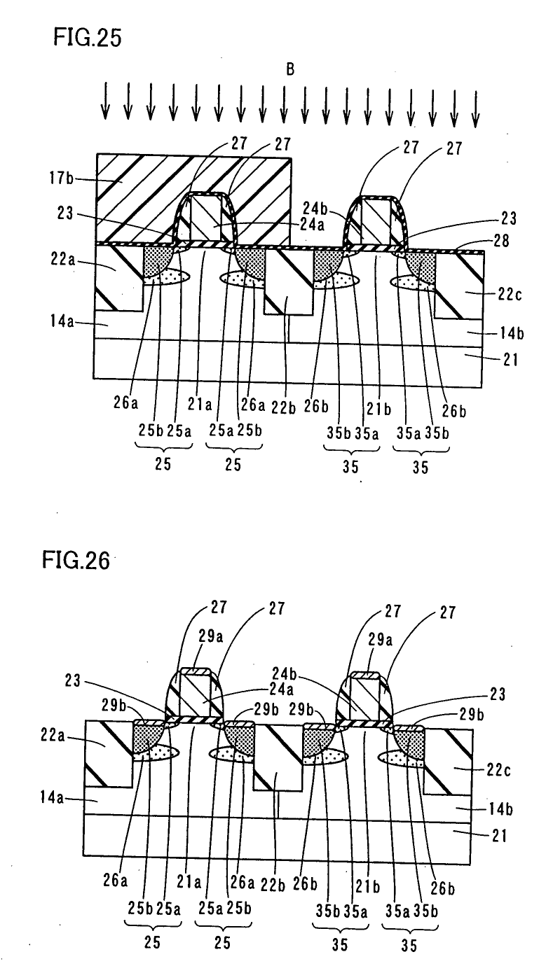

As shown in FIG. 25, another resist film 17b is formed to cover the region to be formed with the n-channel MOS field-effect transistor. The resist film 17b is employed as a mask for ion-implanting boron (B) at implantation energy of about 7 keV and an implantation dosage of about 1×10¹⁵ cm⁻² to about 5×10¹⁵ cm⁻², thereby forming the p-type high-concentration impurity regions 35b constituting the source/drain regions 35 of the p-channel MOS field-effect transistor. At this time, the fluoric regions 26b containing fluorine extend over the junction interfaces between the p-type high-concentration impurity regions 35b and the n well region 14b. Thereafter the resist film 17b is removed.

Heat treatment is performed by RTA at about 700° C. to about 1100° C. for about 0.1 seconds to about 60 seconds, thereby activating the implanted impurities.

Also when the fluoric regions 26a and 26b do not extend over the junction interfaces between the high-concentration impurity regions 25b and 35b and the p and n well regions 14a and 14b upon formation of the aforementioned high-concentration impurity regions 25b and 35b, the high-concentration impurity regions 25b and 35b and the fluoric regions 26a and 26b are diffused through the activation step by RTA. Thus, the fluoric regions 26a and 26b extend over the junction interfaces between the high-concentration impurity regions 25b and 35b and the p and n well regions 14a and 14b.

The aforementioned low-concentration impurity regions 25a and 35a and the high-concentration impurity regions 25b and 35b form the pairs of p-type source/drain regions 25 and 35 having the LDD structure respectively.

Thereafter the silicon nitride film 28 is removed. As shown in FIG. 26, cobalt silicide (CoSi₂) films 29a and 29b are formed on the upper surfaces of the gate electrodes 24a and 24b of polycrystalline silicon and the high-concentration impurity regions 25b and 35b constituting the source/drain regions 25 and 35 respectively in a self-aligned manner through a salicide process.

As shown in FIG. 13, the interlayer dielectric film 30 is formed by CVD and the contact holes 30a, 30b, 30c and 30d are thereafter formed on the prescribed regions by photolithography and dry etching such as RIE. Tungsten is embedded in the contact holes 30a, 30b, 30c and 30d by CVD, thereby forming the plugs 31a, 31b, 31c and 31d respectively. Finally, a multilayer film (not shown) consisting of a Ti layer having a thickness of about 30 nm, a TiN layer having a thickness of about 30 nm and an AlCu layer having a thickness of about 400 nm in ascending order is formed on the upper surface of the interlayer dielectric film 30 and thereafter patterned, thereby forming the upper wires 32a and 32b. The CMOS inverter (semiconductor device) according to the second embodiment is formed in the aforementioned manner.

According to the second embodiment, as hereinabove described, the fluoric regions 26a and 26b are formed to extend over the junction interfaces between the n- and p-type high-concentration impurity regions 25b and 35b and the p and n well regions 14a and 14b respectively, whereby the parasitic capacitances can be reduced around the lower portions (p-n junctions) of the high-concentration impurity regions 25b and 35b constituting the source/drain regions 25 and 35 respectively, similarly to the first embodiment. Consequently, the operating speed of the CMOS inverter can be improved.

Also in the second embodiment, ion implantation is employed for introducing fluorine similarly to the aforementioned first embodiment, so that fluorine can be precisely introduced into prescribed regions of the p and n well regions 14a and 14b. Thus, the parasitic capacitances on the p-n junctions of the source/drain regions 25 and 35 can be reduced without dispersion, similarly to the first embodiment.

Also in the second embodiment, further, no problem is caused by fluctuation of the threshold voltage of the p-channel MOS field-effect transistor also when fluorine reaches the channel regions 21a and 21b located under the gate electrodes 24a and 24b due to small thicknesses of the gate electrodes 24a and 24b employed as masks for ion implanting fluorine. Therefore, reliability of the CMOS inverter can be improved.

### Third Embodiment

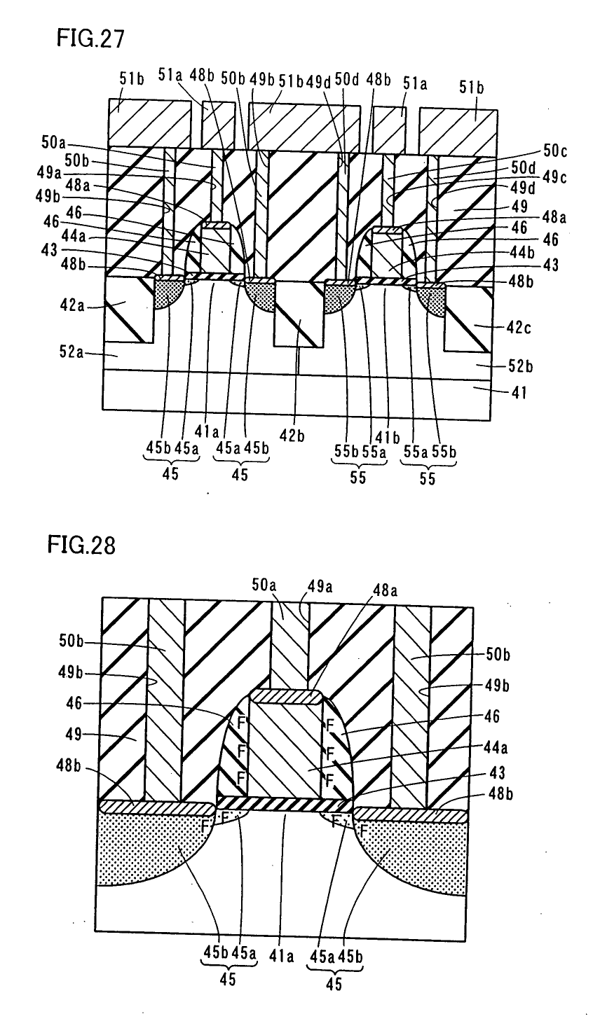

Referring to FIGS. 27 and 28, overlap capacitances between gate electrodes 44a and 44b and source/drain regions 45 and 55 are reduced by introducing fluorine into side wall insulator films 46 in a semiconductor device according to a third embodiment of the present invention.

In the semiconductor device according to the third embodiment, element isolation regions 42a, 42b and 42c are formed on prescribed regions of the main surface of a p-type single-crystalline silicon substrate 41 for isolating an element forming region (active region) from adjacent ones, as shown in FIG. 27. A p well region 52a is formed on a region formed with an n-channel MOS field-effect transistor, while an n well region 52b is formed on a region formed with a p-channel MOS field-effect transistor. A pair of n-type source/drain regions 45 are formed in the p well region 52a to hold a channel region 41a therebetween at a prescribed interval.

Each of the n-type source/drain regions 45 has an LDD structure consisting of an n-type low-concentration impurity region 45a and an n-type high-concentration impurity region 45b. The gate electrode 44a of polycrystalline silicon having a thickness of about 150 nm to about 200 nm is formed on the channel region 41a through the gate insulator film 43 of silicon oxynitride having a thickness of about 2 nm to about 10 nm. The pair of n-type source/drain regions 45, the gate insulator film 43 and the gate electrode 44a form the n-channel MOS field-effect transistor.

A pair of p-type source/drain regions 55 are formed in the n well region 52b to hold a channel region 41b therebetween at a prescribed interval. Each of the p-type source/drain regions 55 has an LDD structure consisting of a p-type low-concentration impurity region 55a and a p-type high-concentration impurity region 55b. The gate electrode 44b of polycrystalline silicon having a thickness of about 150 nm to about 200 nm is formed on the channel region 41b through the gate insulator film 43 of silicon oxynitride having a thickness of about 2 nm to about 10 nm. The pair of p-type source/drain regions 55, the gate insulator film 43 and the gate electrode 44b form the p-channel MOS field-effect transistor.

The side wall insulator films 46 of silicon oxide are formed on the side surfaces of the gate electrodes 44a and 44b constituting the n- and p-channel MOS field-effect transistors respectively. Silicide films 48a and 48b of CoSi₂ are formed on the upper surfaces of the gate electrodes 44a and 44b and the high-concentration impurity regions 45b and 55b respectively.

An interlayer dielectric film 49 of silicon oxide having a thickness of about 1000 nm is formed to cover the overall surface. This interlayer dielectric film 49 has contact holes 49a, 49b, 49c and 49d reaching the silicide films 48a and 48b respectively. Plugs 50a, 50b, 50c and 50d of tungsten ate embedded in the contact holes 49a, 49b, 49c and 49d respectively. Wires 51a and 51b are formed to be connected with the plugs 50a, 50b, 50c and 50d respectively. The wires 51a and 51b consist of Ti layers having a thickness of about 30 nm, TiN layers having a thickness of about 30 nm and AlCu layers having a thickness of about 400 nm in ascending order.

The n- and p-type source/drain regions 45 and 55 of the aforementioned n- and p-channel MOS field-effect transistors are connected with each other through the plugs 50b and 50d and the upper wires 51b. Further, the gate electrodes 44a and 44b of the n- and p-channel MOS field-effect transistors are connected with each other through the plugs 50a and 50c, the upper wires 51a and wires (not shown) located on higher layers. Thus, a CMOS inverter is constituted.

In the semiconductor device according to the third embodiment, fluorine is introduced into the side wall insulator films 46 of the n-channel MOS field-effect transistor and regions of the n-type low- and high-concentration impurity regions 45a and 45b constituting the n-type source/drain regions 45 located in the vicinity of the gate insulator film 43 respectively, as shown in FIG. 28. Thus, the dielectric constants of the side wall insulator films 46 and the regions of the n-type low- and high-concentration impurity regions 45a and 45b constituting the n-type source/drain regions 45 located in the vicinity of the gate insulator film 43 are sufficiently reduced. Also as to the p-channel MOS field-effect transistor, fluorine is introduced into the side wall insulator films 46 and regions of the p-type low- and high-concentration impurity regions 55a and 55b constituting the p-type source/drain regions 55 located in the vicinity of the gate insulator film 43 respectively. Thus, the dielectric constants of the side wall insulator films 46 and the regions of the p-type low- and high-concentration impurity regions 55a and 55b constituting the p-type source/drain regions 55 located in the vicinity of the gate insulator film 43 are sufficiently reduced.

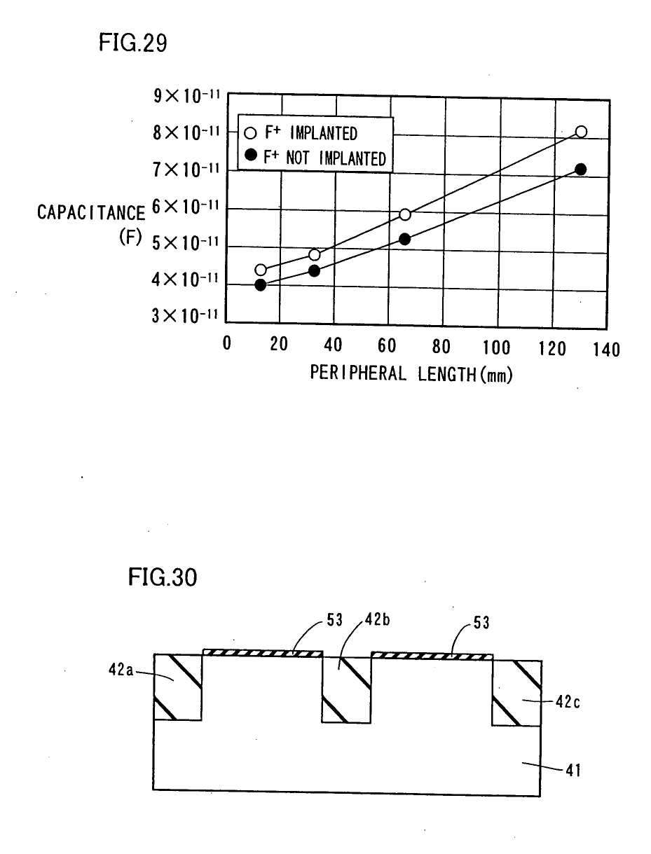

FIG. 29 shows actually measured data indicating overlap capacitances between gate electrodes and source/drain regions in cases of introducing and not introducing fluorine into side wall insulator films and regions around source/drain regions of p-channel MOS field-effect transistors. As understood from FIG. 29, overlap capacitances between the gate electrode and the source/drain regions containing fluorine ions are smaller by about 10% as compared with those between the gate electrode and the source/drain regions containing no fluorine ions.

In the semiconductor device according to the third embodiment, as hereinabove described, both of the overlap capacitances between the source/drain regions 45 and 55 and the gate electrodes 44a and 44b of the n- and p-channel MOS field-effect transistors can be reduced.

A process of fabricating the semiconductor device (CMOS inverter) according to the third embodiment is described with reference to FIGS. 27, 28 and 30 to 43.

As shown in FIG. 30, the element isolation regions 42a, 42b and 42c having the STI structure are formed on the prescribed regions of the main surface of the p-type single-crystalline silicon substrate 41 for isolating the active region from the adjacent ones. Thereafter the surface of the p-type single-crystalline silicon substrate 41 is oxidized, thereby forming a sacrifice oxide film 53 of silicon dioxide.

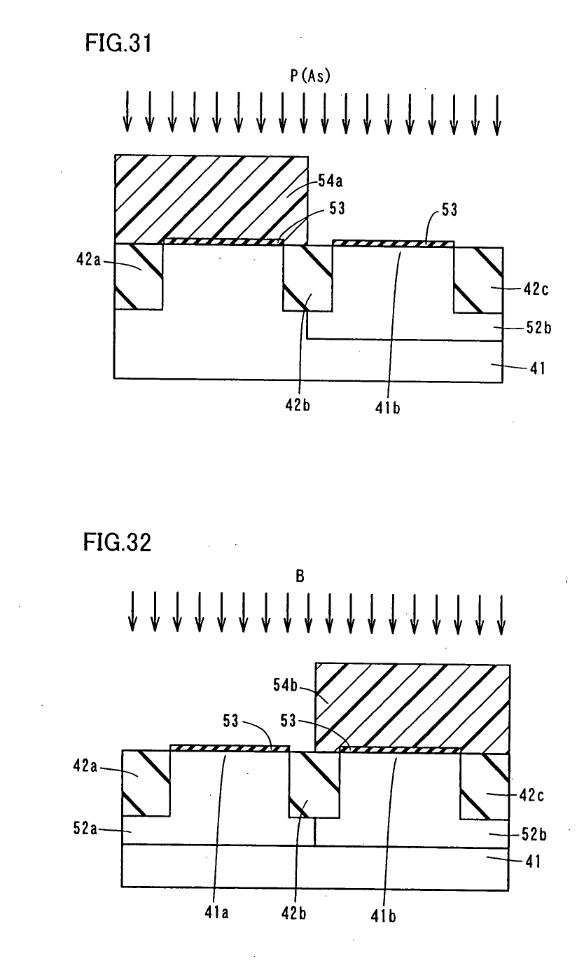

As shown in FIG. 31, a resist film 54a is formed by lithography to cover the region to be formed with the n-channel MOS field-effect transistor. Thereafter the resist film 54a is employed as a mask for ion-implanting phosphorus (P) into the p-type single-crystalline silicon substrate 41 through the sacrifice oxide film 53 at implantation energy of about 380 keV and an implantation dosage of about 4×10¹³ cm⁻², thereby forming the n well region 52b. Further, arsenic (As) is ion-implanted at implantation energy of about 100 keV to about 140 keV and an implantation dosage of about 0.5×10¹² cm⁻² to about 1×10¹³ cm⁻², thereby adjusting the impurity concentration in the channel region 41b. Thus, the threshold voltage is optimized. Thereafter the resist film 54a is removed.

As shown in FIG. 32, another resist film 54b is formed by lithography to cover the region to be formed with the p-channel MOS field-effect transistor. Thereafter the resist film 54b is employed as a mask for ion-implanting boron (B) into the p-type single-crystalline silicon substrate 41 through the sacrifice oxide film 53 at implantation energy of about 190 keV and an implantation dosage of about 4×10¹³ cm⁻², thereby forming the p well region 52a. Further, boron (B) is ion-implanted at implantation energy of about 10 keV to about 30 keV and an implantation dosage of about 1×10¹² cm⁻² to about 1×10¹³ cm⁻², thereby adjusting the impurity concentration in the channel region 41a. Thus, the threshold voltage is optimized. Thereafter the resist film 54b is removed.

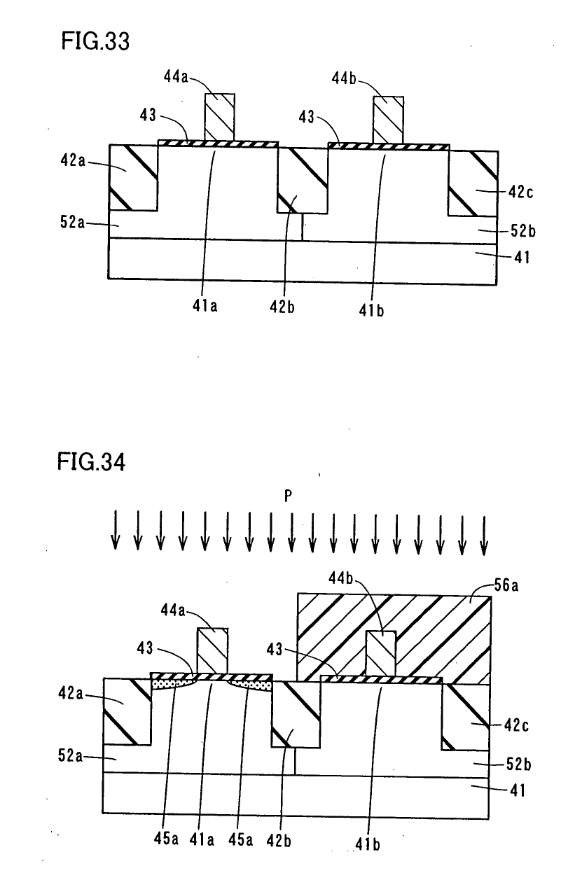

As shown in FIG. 33, heat treatment is performed in an oxidizing atmosphere for forming a silicon dioxide film on the surface of the p-type single-crystalline silicon substrate 41 with a thickness of about 2 nm to about 10 nm and annealing is thereafter performed in an NO atmosphere, thereby forming the gate insulator films 43 of silicon oxynitride having the thickness of about 2 nm to about 10 nm on the surface of the single-crystalline silicon substrate 41. Thereafter a polysilicon film (not shown) is deposited on the overall surface by CVD with a thickness of about 150 nm to about 200 nm and thereafter patterned by general photolithography and etching by RIE, thereby forming the gate electrodes 44a and 44b of polycrystalline silicon. The gate insulator films 43, remarkably damaged by the aforementioned etching, are reoxidized after formation of the gate electrodes 44a and 44b.

As shown in FIG. 34, another resist film 56a is formed to cover the region to be formed with the p-channel MOS field-effect transistor. Thereafter the resist film 56a is employed as a mask for ion-implanting phosphorus (P) into the main surface of the p well region 52a at implantation energy of about 30 keV, an implantation dosage of about 0.5×10¹³ cm⁻² to about 5×10¹⁴ cm⁻² and an incidence angle of about 7° four times while rotating the p-type single-crystalline silicon substrate 41 by 90°. Thus, the n-type low-concentration impurity regions 45a are formed. Thereafter the resist film 56a is removed.

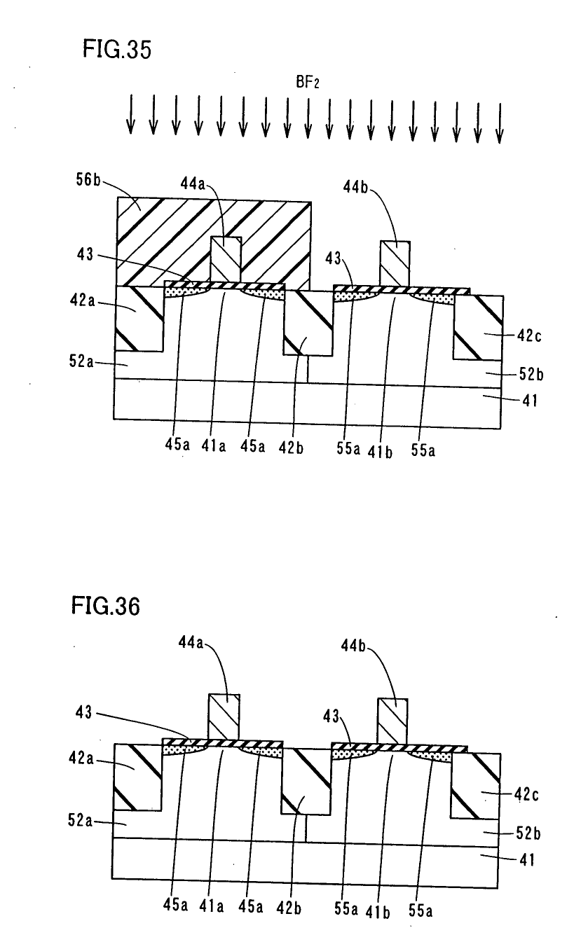

As shown in FIG. 35, still another resist film 56b is formed to cover the region to be formed with the n-channel. MOS field-effect transistor. Thereafter the resist film 56b is employed as a mask for ion-implanting boron difluoride (BF₂) into the main surface of the n well region 52b at implantation energy of about 15 keV, an implantation dosage of about 1×10¹³ cm⁻² to about 5×10¹⁴ cm⁻² and an incidence angle of about 7° four times while rotating the p-type single-crystalline silicon substrate 41 by 90°. Thus, the p-type low-concentration impurity regions 55a are formed. Thereafter the resist film 56b is removed, as shown in FIG. 36.

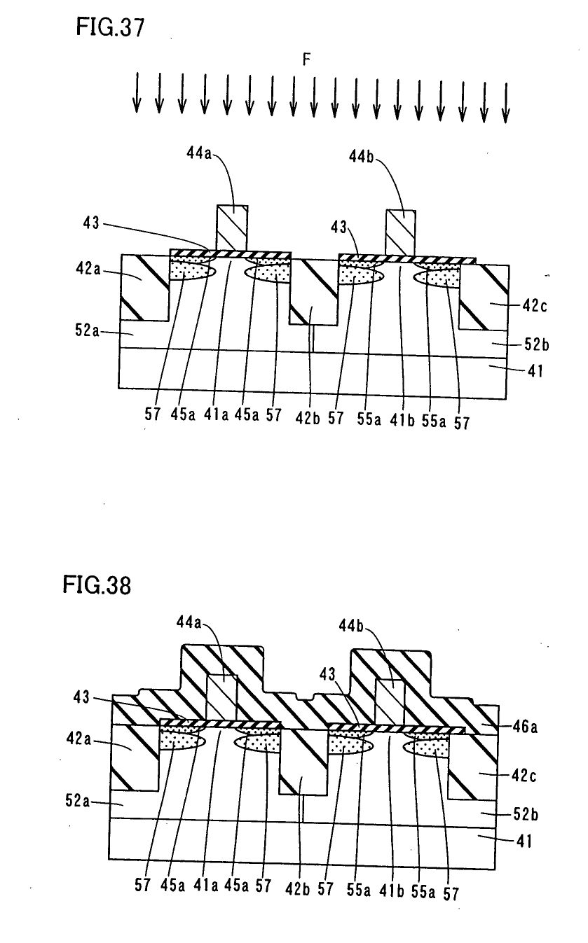

As shown in FIG. 37, fluorine (F) is ion-implanted into the overall surface at implantation energy of about 10 keV and an implantation dosage of about 3×10¹⁵ cm⁻². Thus, fluorine ions are implanted into the gate electrodes 44a and 44b while fluoric regions 57 containing fluorine are formed on the p and n well regions 52a and 52b respectively.

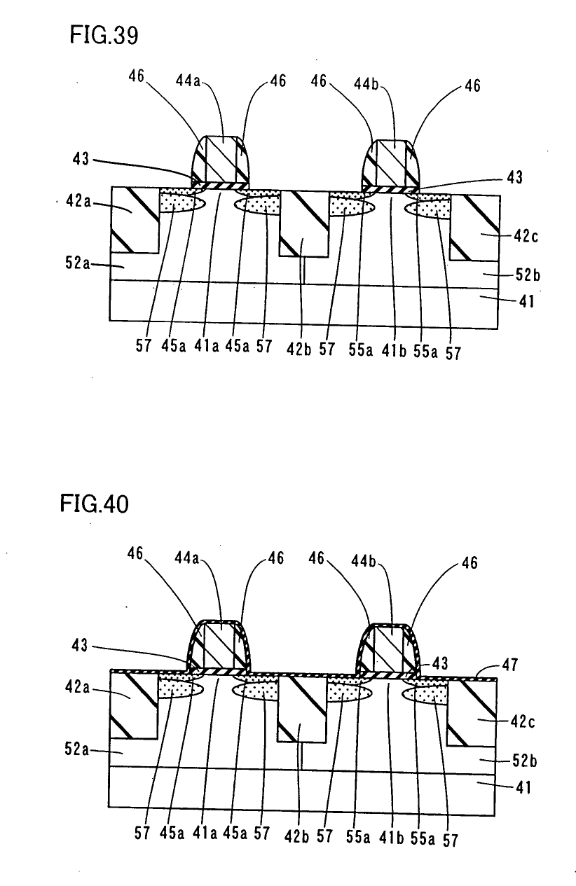

As shown in FIG. 38, an insulator film 46a of silicon oxide is deposited on the overall surface by thermal CVD. This insulator film 46a is etched back by RIE, thereby forming the side wall insulator films 46 of silicon oxide on the side surfaces of the gate electrodes 44a and 44b as shown in FIG. 39. In the aforementioned etch-back step, portions of the gate insulator films 43 excluding regions located immediately under the gate electrodes 44a and 44b and the side wall insulator films 46 are removed.

As shown in FIG. 40, a silicon nitride film 47 having a thickness of about 5 nm to about 20 nm is deposited on the overall surface. This silicon nitride film 47 is formed for preventing channeling in a later ion implantation step for forming the high-concentration impurity regions 45b and 55b and inhibiting fluorine from outward diffusion in later heat treatment.

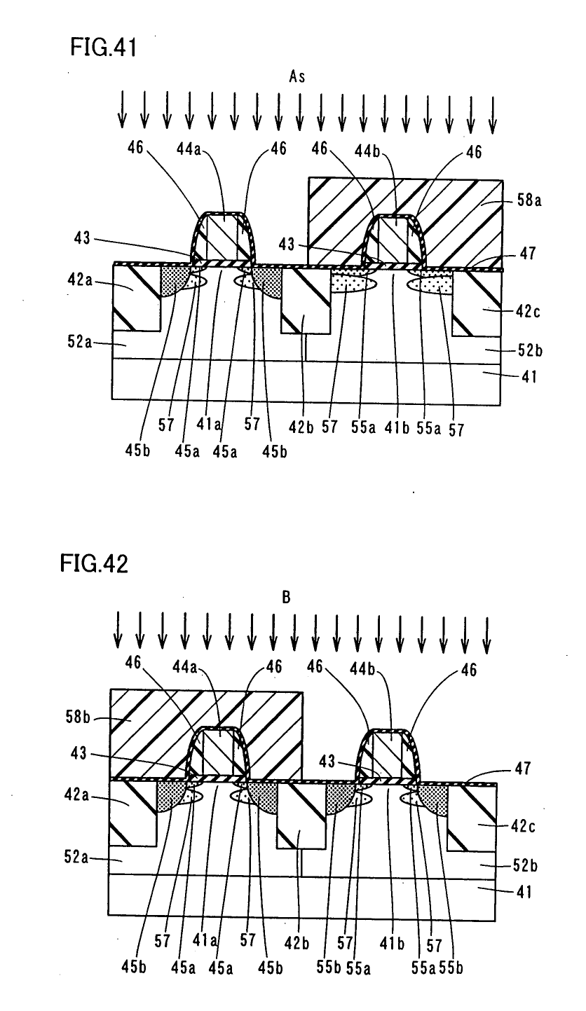

As shown in FIG. 41, a resist film 58a is formed to cover the region to be formed with the p-channel MOS field-effect transistor. Thereafter the resist film 58a is employed as a mask for ion-implanting arsenic (As) into the p-type single-crystalline silicon substrate 41 at implantation energy of about 45 keV and an implantation dosage of about 1×10¹⁵ cm⁻² to about 5×10¹⁵ cm⁻², thereby forming the n-type high-concentration impurity regions 45b constituting the source/drain regions 45 of the n-channel MOS field-effect transistor. Thereafter the resist film 58a is removed.

As shown in FIG. 42, another resist film 58b is formed to cover the region to be formed with the n-channel MOS field-effect transistor. Thereafter the resist film 58b is employed as a mask for ion-implanting boron (B) at implantation energy of about 7 keV and an implantation dosage of about 1×10¹⁵ cm⁻² to about 5×10¹⁵ cm⁻², thereby forming the p-type high-concentration impurity regions 55b constituting the source/drain regions 55 of the p-channel MOS field-effect transistor. Thereafter the resist film 58b is removed. Heat treatment is performed by RTA at about 700° C. to about 1100° C. for about 0.1 seconds to about 60 seconds, thereby activating the implanted impurities.

The aforementioned low-concentration impurity regions 45a and 55a and the high-concentration impurity regions 45b and 55b form the pairs of p-type source/drain regions 45 and 55 having the LDD structure respectively.

In the aforementioned heat treatment by RTA, fluorine present in the gate electrodes 44a and 44b is diffused into the side wall insulator films 46. Fluorine contained in the fluoric regions 57 located in the p and n well regions 52a and 52b is also diffused into the side wall insulator films 46, the low-concentration impurity regions 45a and 55a and regions of the high-concentration impurity regions 45b and 55b close to the gate insulator films 43. At this time, the silicon nitride film 47 prevents fluorine from outward diffusion through the p-type single crystalline silicon substrate 41. Thus, fourine can be introduced into at least the regions of the n-channel MOS field-effect transistor shown in FIG. 28. This also applies to distribution of fluorine in the p-channel MOS field-effect transistor. Thereafter the silicon nitride film 47 is removed.

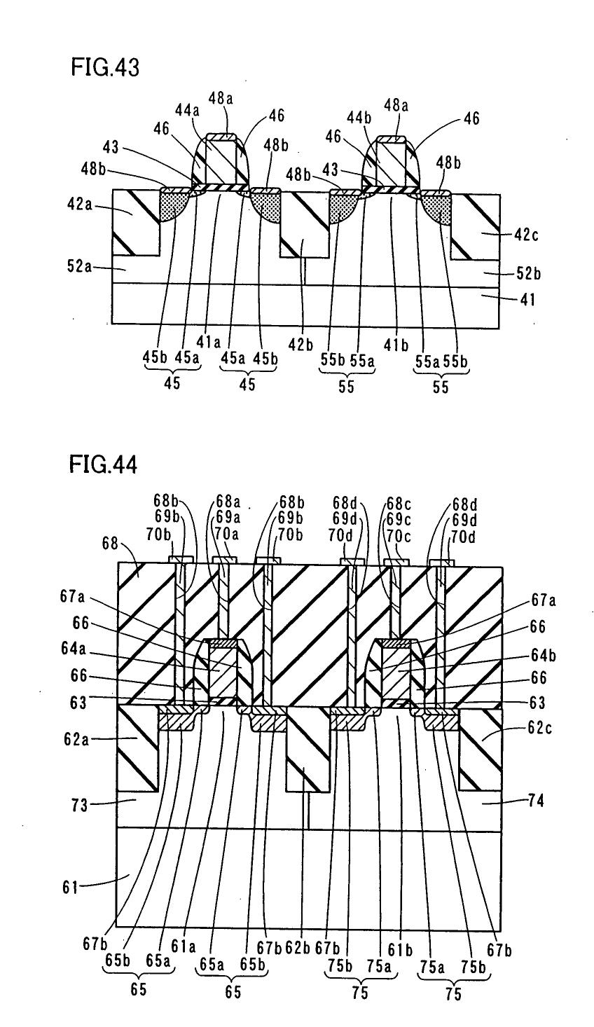

As shown in FIG. 43, silicide films 48a and 48b of cobalt silicide (CoSi₂) are formed on the upper surfaces of the gate electrodes 44a and 44b of polycrystalline silicon and the high-concentration impurity regions 45b and 55b constituting the source/drain regions 45 and 55 respectively in a self-aligned manner through a salicide process.

As shown in FIG. 27, the interlayer dielectric film 49 is formed by CVD and the contact holes 49a, 49b, 49c and 49d are thereafter formed on the prescribed regions by photolithography and dry etching such as RIE. Tungsten is embedded in the contact holes 49a, 49b, 49c and 49d by CVD, thereby forming the plugs 50a, 50b, 50c and 50d respectively. Finally, a multilayer film consisting of a Ti layer having a thickness o about 30 nm, a TiN layer having a thickness of about 30 nm and an AlCu layer having a thickness of about 400 nm in ascending order is formed on the upper surface of the interlayer dielectric film 49 and thereafter patterned, thereby forming the upper wires 51a and 51b. The CMOS inverter (semiconductor device) according to the third embodiment is formed in the aforementioned manner.

According to the third embodiment, as hereinabove described, fluorine ion-implanted into the gate electrodes 44a an 44b is thermally diffused into the side wall insulator films 46, consisting of silicon oxide films, of the n- and p-channel MOS field-effect transistors so that the dielectric constant of the side wall insulator films 46 can be reduced, whereby the overlap capacitances caused between the gate electrodes 44a and 44b and the source/drain regions 45 and 55 of the n- and p-channel MOS field-effect transistors can be sufficiently reduced. Consequently, the operating speed of the semiconductor device (CMOS inverter) can be improved.

According to the third embodiment, further, fluorine is diffused into the side wall insulator films 46 of the n- and p-channel MOS field-effect transistors also from the fluoric regions 57 located in the p and n well regions 52a and 52b as hereinabove described, whereby the dielectric constant of the side wall insulator films 46 can be further reduced. Thus, the overlap capacitances caused between the gate electrodes 44a and 44b and the source/drain regions 45 and 55 of the n- and p-channel MOS field-effect transistors can be further sufficiently reduced. Further, fluorine is introduced also into the low-concentration impurity regions 45a and 55a and the regions of the high-concentration impurity regions 45b and 55b close to the gate insulator films 43, whereby the overlap capacitances can be further reduced. Consequently, the operating speed of the semiconductor device can be further improved.

According to the third embodiment, in addition, the silicon nitride film 47 is formed on the overall surface after formation of the side wall insulator films 46, whereby fluorine ion-implanted into the gate electrodes 44a and 44b and diffused into the side wall insulator films 46 by heat treatment can be prevented from outward diffusion through the side wall insulator films 46. Thus, the dielectric constant of the silicon oxide films constituting the side wall insulator films 46 can be so sufficiently reduced that the overall capacitances caused between the source/drain regions 45 and 55 and the gate electrodes 44a and 44b of the n- and p-channel MOS field-effect transistors can be further sufficiently reduced. Consequently, the operating speed of the semiconductor device can be further improved.

### Fourth Embodiment

Referring to FIG. 44, fluorine is introduced into the gate insulator film and the interface between the gate insulator film and the central portions of channel regions 61a and 61b for terminating dangling bonds in a semiconductor device according to a fourth embodiment of the present invention.

In the semiconductor device according to the fourth embodiment, element isolation regions 62a, 62b and 62c are formed on prescribed regions of the main surface of a p-type single-crystalline silicon substrate 61 for isolating an element forming region (active region) from adjacent ones, as shown in FIG. 44. A p well region 73 is formed on a region of the p-type single-crystalline silicon substrate 61 formed with an n-channel MOS field-effect transistor, and an n well region 74 is formed on a region formed with a p-channel transistor. The p and n well regions 73 and 74 are examples of the “semiconductor region” in the present invention. A pair of n-type source/drain regions 65 are formed in the p well region 73 to hold the channel region 61a therebetween at a prescribed interval. Each of the n-type source/drain regions 65 has an LDD structure consisting of an n-type low-concentration impurity region 65a and an n-type high-concentration impurity region 65b. The n-type source/drain regions 65 are examples of the “impurity region” in the present invention. A gate electrode 64a of polycrystalline silicon is formed on the channel region 61a through a gate insulator film 63 of silicon oxynitride. The pair of n-type source/drain regions 65, the gate insulator film 63 and the gate electrode 64a form the n-channel MOS field-effect transistor.

A pair of p-type source/drain regions 75 are formed in the n well region 74 to hold the channel region 61b therebetween at a prescribed interval. Each of the p-type source/drain regions 75 has an LDD structure consisting of a p-type low-concentration impurity region 75a and a p-type high-concentration impurity region 75b. The p-type source/drain regions 75 are examples of the “impurity region” in the present invention. A gate electrode 64b of polycrystalline silicon is formed on the channel region 61b through a gate insulator film 63 of silicon oxynitride. The pair of p-type source/drain regions 75, the gate insulator film 63 and the gate electrode 64b form the p-channel MOS field-effect transistor.

According to the fourth embodiment, fluorine is introduced into the gate insulator films 63 and the interface between the gate insulator film and the overall channel regions 61a and 61b.

Side wall insulator films 66 of silicon oxide or the like are formed on the side surfaces of the gate electrodes 64a and 64b constituting the n- and p-channel MOS field-effect transistors. Silicide films 67a and 67b of CoSi₂ are formed on the upper surfaces of the gate electrodes 64a and 64b and the high-concentration impurity regions 65b and 75b constituting the source/drain regions 65 and 75 respectively.

An interlayer dielectric film 68 of silicon oxide is formed to cover the overall surface. The interlayer dielectric film 68 has contact holes 68a, 68b, 68c and 68d reaching the silicide films 67a and 67b respectively. Plugs 69a, 69b, 69c and 69d of tungsten are embedded in the contact holes 68a, 68b, 68c and 68d respectively. Wires 70a, 70b, 70c and 70d are formed to be connected with the plugs 69a, 69b, 69c and 69d respectively.

In the semiconductor device according to the fourth embodiment, as hereinabove described, fluorine is introduced into the interface between the gate insulator film and the overall channel regions 61a and 61b so that dangling bonds can be terminated with this fluorine along the overall channel regions 61a and 61b. Fluorine is also introduced into the gate insulator films 63, so that dangling bonds in the gate insulator films 63 can also be terminated with this fluorine. Thus, the threshold voltages can be inhibited from fluctuation resulting from dangling bonds. Further, saturation currents can also be inhibited from fluctuation resulting from dangling bonds.

According to the fourth embodiment, as hereinabove described, dangling bonds are terminated with fluorine ions bonded to silicon atoms with bond energy stronger than that of hydrogen, whereby the characteristics of the transistors can be stabilized over a long period.

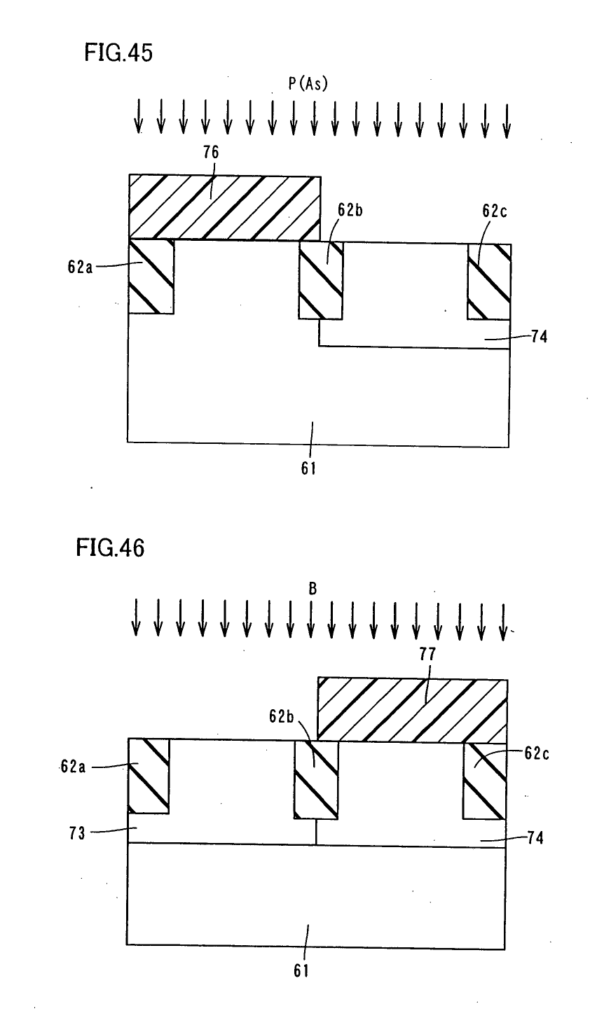

A process of fabricating the semiconductor device according to the fourth embodiment is described with reference to FIGS. 45 to 54.

As shown in FIG. 45, the element isolation regions 62a, 62b and 62c having the STI structure are formed on the p-type single-crystalline silicon substrate 61. A resist film 76 is formed on the region to be formed with the n-channel MOS field-effect transistor. The resist film 76 is employed as a mask for ion-implanting phosphorus (P) into the p-type single-crystalline silicon substrate 61, thereby forming the n well region 74. The resist film 76 is again employed as a mask for ion-implanting arsenic (As) from above the n well region 74, in order to adjust the threshold voltage. At this time, arsenic (As) is implanted at an implantation dosage of about 0.5×10¹² cm⁻² to about 1×10¹³ cm⁻² and implantation energy of about 120 keV. Thereafter the resist film 76 is removed.

As shown in FIG. 46, another resist film 77 is formed to cover the region to be formed with the p-channel MOS field-effect transistor. The resist film 77 is employed as a mask for ion-implanting boron (B) into the p-type single-crystalline silicon substrate 61, thereby forming the p well region 573. The resist film 77 is again employed as a mask for ion-implanting boron (B) into the surface of the p well region 73, in order to adjust the threshold voltage. At this time, boron (B) is implanted at an implantation dosage of about 1×10¹² cm⁻² to about 1×10¹³ cm⁻² and implantation energy of about 20 keV. Thereafter the resist film 77 is removed.

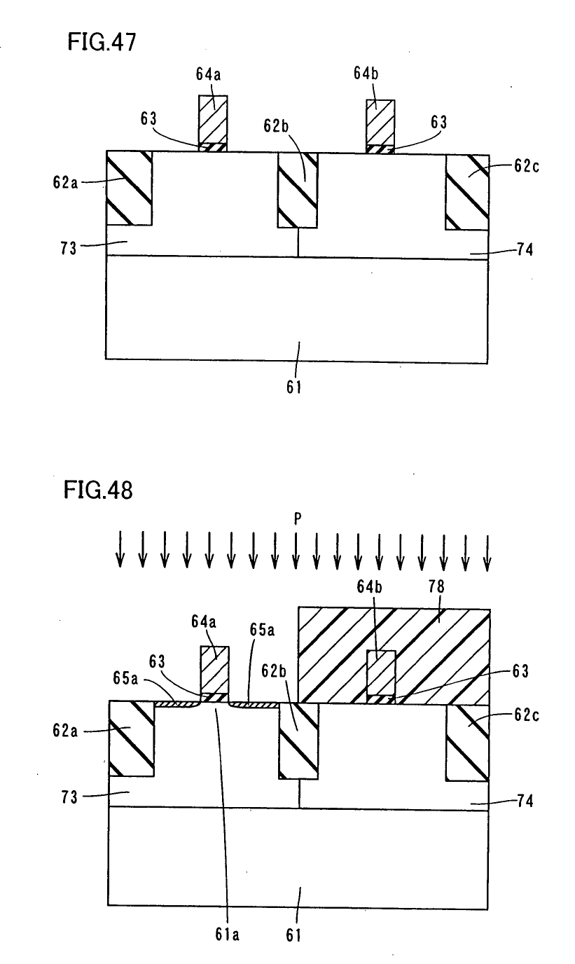

As shown in FIG. 47, heat treatment is performed in an oxidizing atmosphere for forming a silicon dioxide film on the surface of the p-type single-crystalline silicon substrate 61 with a thickness of about 2 nm to about 10 nm and annealing is thereafter performed in an NO atmosphere, thereby forming the gate insulator films 63 of silicon oxynitride having the thickness of about 2 nm to about 10 nm on the surface of the p-type single-crystalline silicon substrate 61. Thereafter a polysilicon film (not shown) is deposited on the overall surface by CVD with a thickness of about 150 nm to about 200 nm and thereafter patterned by general photolithography and RIE, thereby forming the gate electrodes 64a and 64b of polycrystalline silicon. According to the fourth embodiment, the gate electrodes 64a and 64b are formed to have a thickness of about 200 nm and a gate length of about 0.3 μm to about 1 μm.

The gate insulator films 63, remarkably damaged by the etching for forming the gate electrodes 64a and 64b, are reoxidized after formation of the gate electrodes 64a and 64b.

As shown in FIG. 48, another resist film 78 is formed to cover the region to be formed with the p-channel MOS field-effect transistor. The resist film 78 is employed as a mask for ion-implanting phosphorus (P) at implantation energy of about 30 keV, an implantation dosage of about 0.5×10¹³ cm⁻² to about 5×10¹⁴ cm⁻² and an incidence angle of about 7° four times while rotating the p-type single-crystalline silicon substrate 61 by 90°. Thus, the n-type low-concentration impurity regions 65a are formed. Thereafter the resist film 78 is removed.

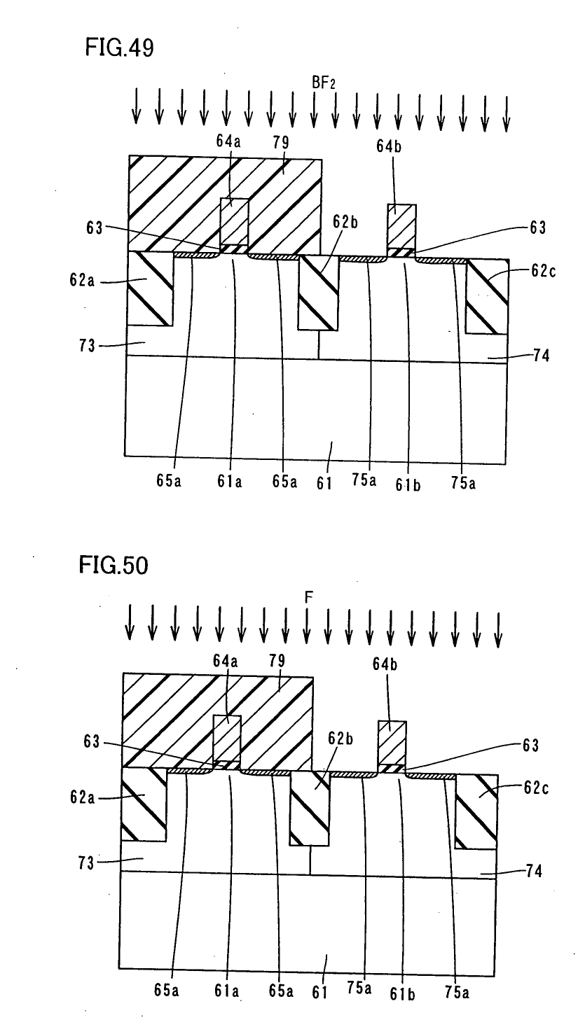

As shown in FIG. 49, still another resist film 79 is formed to cover the region to be formed with the n-channel MOS field-effect transistor. Thereafter boron difluoride (BF₂) is ion-implanted into the main surface of the n well region 74 at implantation energy of about 15 keV, an implantation dosage of about 1×10¹³ cm⁻² to about 5×10¹⁴ cm⁻² and an incidence angle of about 7° four times while rotating the p-type single-crystalline silicon substrate 61 by 90°. Thus, the p-type low-concentration impurity regions 75a are formed.

As shown in FIG. 50, the resist film 79 is employed as a mask for ion-implanting fluorine (F) into the low concentration impurity regions 75a and the gate electrode 64b constituting the p-channel MOS field-effect transistor at implantation energy of about 20 keV and an implantation dosage of about 3×10¹⁵ cm⁻² to about 5×10¹⁵ cm⁻². The fluorine implantation conditions are so set that no fluorine ions reach the gate insulator film 63 through the gate electrode 64b. Therefore, fluorine ions are implanted into a position of the gate electrode 64b close to the gate insulator film 63.

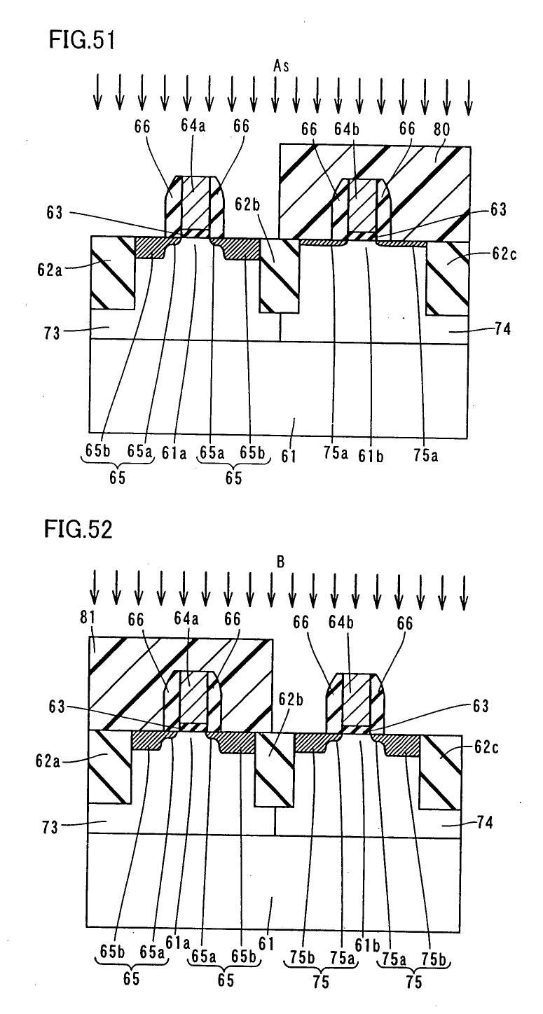

As shown in FIG. 51, an insulator film (not shown) of silicon oxide or the like is deposited on the overall surface by CVD and thereafter etched back by RIE, thereby forming the side wall insulator films 66 on the side surfaces of the gate electrodes 64a and 64b. Thereafter a resist film 80 is formed to cover the region to be formed with the p-channel MOS field-effect transistor and thereafter employed as a mask for ion-implanting arsenic (As) into the main surface of the p well region 73 at implantation energy of about 45 keV and an implantation dosage of about 1×10¹⁵ cm⁻² to about 5×10¹⁵ cm⁻², thereby forming the n-type high-concentration impurity regions 65b constituting the source/drain regions 65 of the n-channel MOS field-effect transistor. Thereafter the resist film 80 is removed.

As shown in FIG. 52, another resist film 81 is formed to cover the region to be formed with the n-channel MOS field-effect transistor. The resist film 81 is employed as a mask for ion-implanting boron (B) at implantation energy of about 7 keV and an implantation dosage of about 5×10¹⁵ cm⁻², thereby forming the p-type high-concentration impurity regions 75b constituting the p-type source/drain regions 75. Thereafter the resist film 81 is removed.

Thereafter heat treatment is performed by RTA, in order to activate the implanted impurities while diffusing fluorine implanted into the gate electrode 64b. This heat treatment by RTA is performed at an atmosphere temperature of about 1050° C. for about 5 seconds. Fluorine is diffused from the gate electrode 64b and the low-concentration impurity regions 75a due to the heat treatment by RTA. Fluorine is diffused at a higher rate in the gate electrode 64b than in the p-type silicon substrate 61. Therefore, fluorine is diffused from the gate electrode 64b into the interface between the gate insulator film 63 and the n well region 74 through the gate insulator film 63. At this time, fluorine is also diffused from the low-concentration impurity regions 75a gradually toward the central region of the channel region 61b.

Fluorine is thus diffused from the gate electrode 64b into the interface between the gate insulator film and the channel region 61b through the gate insulator film 63, so that fluorine can be easily diffused into the overall channel region 61b also when the p-channel MOS field-effect transistor has a large channel length. In this case, the time required for diffusing fluorine from the gate electrode 64b into the interface between the gate insulator film 63 and the p-type single-crystalline silicon substrate 61 is extremely short as compared with that for diffusing fluorine from only the low-concentration impurity regions 75a. Fluorine can be diffused from the gate electrode 64b and the low-concentration impurity regions 75a through only single heat treatment by RTA, whereby the fabrication process can be simplified.

As shown in FIG. 44, cobalt silicide (CoSi₂) films 67a and 67b are formed on the upper surfaces of the gate electrodes 64a and 64b of polycrystalline silicon and the high-concentration impurity regions 65b and 75b respectively in a self-aligned manner through a salicide process. The interlayer dielectric film 68 is formed by CVD and the contact holes 68a, 68b, 68c and 68d are thereafter formed on the prescribed regions by photolithography and dry etching such as RIE. Tungsten is embedded in the contact holes 68a, 68b, 68c and 68d by CVD, thereby forming the plugs 69a, 69b, 69c and 69d respectively. Finally, upper wires 70a, 70b, 70c and 70d of aluminum or the like are formed on the upper surface of the interlayer dielectric film 68 to be connected with the plugs 69a, 69b, 69c and 69d respectively.

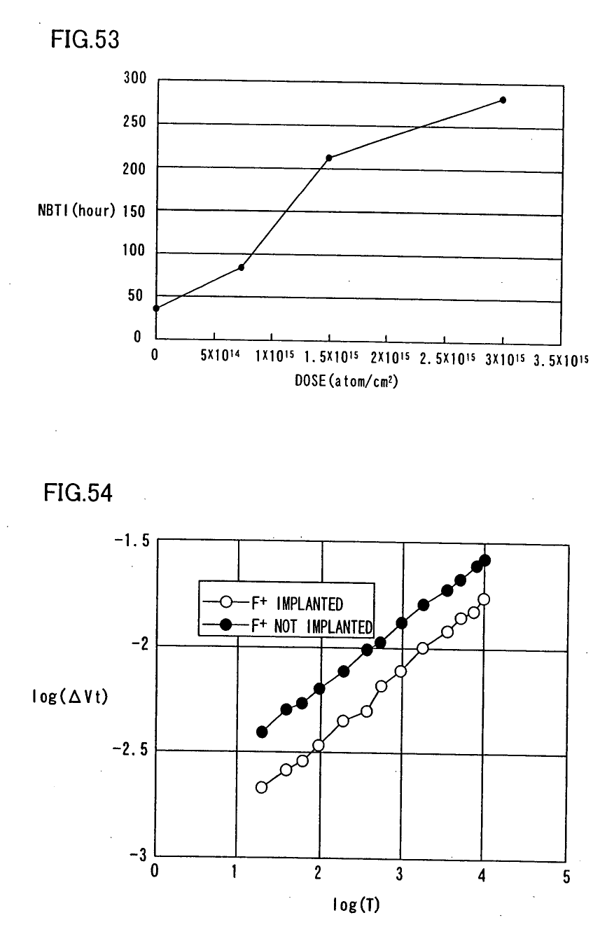

FIG. 53 shows the relation between the dose (implantation dosage) of fluorine ions and NBTI (negative bias temperature instability) lifetime. The abbreviation NBTI stands for such a characteristic that the drivability of a transistor is deteriorated when a negative voltage is continuously applied to a gate electrode with respect to a substrate at a high temperature. Referring to FIG. 53, the axis of abscissa shows the dose (atom/cm²) of fluorine ions, and the axis of ordinate shows the time (life up to deterioration of the characteristics of a semiconductor device). It is understood from FIG. 53 that the life up to deterioration of the characteristics of the semiconductor device is increased as the dose (implantation rate) of the fluorine ions is increased.

FIG. 54 shows change (ΔVt) of a threshold voltage following a voltage application time (T) in a semiconductor device. Referring to FIG. 54, the axis of abscissa shows the time, and the axis or ordinate the change (ΔVt) of the threshold voltage. The change (ΔVt) of the threshold voltage is measured by applying a voltage of 0 V to source/drain regions of a p-channel MOS field-effect transistor and a substrate while applying a voltage of −4.6 V to a gate electrode respectively. It is understood from FIG. 54 that the semiconductor device according to the fourth embodiment containing fluorine exhibits smaller change (ΔVt) of the threshold voltage as compared with a conventional semiconductor device containing no fluorine. Thus, it is possible to confirm that the change (ΔVt) of the threshold voltage can be reduced by implanting fluorine.

In the aforementioned process of fabricating the semiconductor device according to the fourth embodiment, fluorine is diffused from the gate electrode 64b into the channel regions 61b through the gate insulator film 63 and from the low-concentration impurity regions 75a into the channel region 61b so that the same can be diffused into the gate insulator film 63 and a larger quantity of fluorine can be diffused into the overall channel region 61b. Thus, a larger quantity of dangling bonds present in the overall gate insulator film 63 and the overall channel region 61b can be terminated with fluorine. Consequently, the threshold voltage of the p-channel MOS field-effect transistor can be further inhibited from remarkable fluctuation resulting from dangling bonds in the interface between the gate insulator film and the central region of the channel region 61b when the quantity of dangling bonds in the gate insulator film 63 and the gate length (channel length) are large.

Although the present invention has been described and illustrated in detail, it is clearly understood that the same is by way of illustration and example only and is not to be taken by way of limitation, the spirit and scope of the present invention being limited only by the terms of the appended claims.

For example, while the above first embodiment has been described with reference to the method of forming the p-channel MOS field-effect transistor, the present invention is not restricted to this but may alternatively be applied to an n-channel MOS field-effect transistor.

While the parasitic capacitances caused on the p-n junction interfaces of the source/drain regions 5 or 25 are reduced by introducing fluorine in each of the aforementioned first and second embodiments, the present invention is not restricted to this but carbon may alternatively be introduced. Carbon, an element forming bonds with silicon similarly to fluorine, having smaller mass than silicon and serving as neither donor nor acceptor, can reduce the dielectric constant of the silicon substrate 1 or 21. In practice, the dielectric constant of SiC, which is about 7, is lower than the dielectric constant of Si, which is about 11. Therefore, the parasitic capacitances cased on the p-n junctions can be reduced with carbon. A similar effect can be attained also when both of fluorine and carbon are introduced.

While fluorine is ion-implanted at the implantation energy of about 20 keV and the implantation dosage of about 3×10¹⁵ cm⁻² thereby forming the fluoric regions 6 or 26a and 26b containing fluorine in each of the aforementioned first and second embodiments, the fluoric regions 6 or 26a and 26b may alternatively be formed by ion-implanting fluorine at implantation energy of about 5 keV to about 30 keV and an implantation dosage of about 1.5×10¹⁵ cm⁻² to about 3×10¹⁵ cm⁻². In this case, the threshold voltages do not fluctuate beyond tolerance.

While fluorine is ion-implanted into the overall surface after formation of the low-concentration impurity regions 5a as shown in FIG. 7 in the aforementioned first embodiment, this ion implantation step may alternatively be carried out in a stage other than that after formation of the low-concentration impurity regions 5a. For example, this step may be carried out before formation of the element isolation regions 2a and 2b shown in FIG. 3, or before or after the step of ion-implanting arsenic (As) for adjusting the threshold voltage shown in FIG. 4. Further alternatively, the step may be carried out before formation of the gate electrode 4 shown in FIG. 5 or after formation of the high-concentration impurity regions 5b shown in FIG. 10. Further, fluorine may be ion-implanted not into the overall surface but into part of the n-type single-crystalline silicon substrate 1 through an ion implantation mask.

In the second embodiment, fluorine, ion-implanted into the overall surface after formation of the low-concentration impurity regions 25a and 35a as shown in FIG. 21, may alternatively be ion-implanted in a stage other than that after formation of the low-concentration impurity regions 25a and 35a. For example, fluorine may alternatively be ion-implanted before formation of the element isolation regions 22a, 22b and 22c shown in FIG. 14, or after formation of the sacrifice oxide film 36. Further alternatively, fluorine may be ion-implanted before or after the ion implantation steps for forming the n and p well regions 14b and 14a shown in FIGS. 15 and 16. Further alternatively, fluorine may be ion-implanted before or after the step of ion-implanting arsenic (As) for adjusting the threshold voltage shown in FIG. 15 or before or after the step of ion-implanting boron (B) for adjusting the threshold voltage shown in FIG. 16. Further alternatively, fluorine may be ion-implanted before formation of the gate electrodes 24a and 24b shown in FIG. 17, after formation of the n-type high-concentration impurity regions 25b shown in FIG. 24 or after formation of the p-type high-concentration impurity regions 35b shown in FIG. 25.

While the plugs 11a and 11b, 31a to 31d, 50a to 50d or 69a to 69d of tungsten are directly embedded in the contact holes 10a and 10b, 30a to 30d, 49a to 49d or 68a to 68d in each of the aforementioned first to fourth embodiments, barrier layers consisting of Ti layers having a thickness of about 10 nm and TiN layers having a thickness of about 10 nm may alternatively be formed before embedding the plugs 11a and 11b, 31a to 31d, 50a to 50d or 69a to 69d of tungsten in the contact holes 10a and 10b, 30a to 30d, 49a to 49d or 68a to 68d.

While fluorine is introduced into the side wall insulator films 46 of the CMOS inverter in the aforementioned third embodiment, the present invention is not restricted to this but fluorine may alternatively be introduced into the side wall insulator films 46 of either the n-channel MOS field-effect transistor or the p-channel MOS field-effect transistor.

While the overlap capacitances between the gate electrodes 44a and 44b and the source/drain regions 45 and 55 are reduced by introducing fluorine in the aforementioned third embodiment, the present invention is not restricted to this but a similar effect can be attained also when an element reducing the dielectric constant other than fluorine is introduced. For example, carbon is considerable as the element reducing the dielectric constant other than fluorine.

While the silicon oxide films (insulator films) constituting the side wall insulator films 46 are formed by thermal CVD in the aforementioned third embodiment, the present invention is not restricted to this but the side wall insulator films 46 may alternatively be formed by plasma CVD and thereafter subjected to heat treatment at a temperature of about 400° C. Also in this case, fluorine can be diffused from the gate electrodes 44a and 44b into the side wall insulator films 46.

While silicon oxide films are employed as the materials constituting the side wall insulator films 46 containing fluorine in the aforementioned third embodiment, the present invention is not restricted to this but fluorine may alternatively be introduced into side wall insulator films consisting of insulator films, containing Si, other than silicon oxide films. Further alternatively, fluorine may be introduced into side wall insulator films consisting of insulator films containing no Si.

While fluorine is ion-implanted at the implantation energy of about 10 keV and the implantation dosage of about 3×10¹⁵ cm⁻² in the aforementioned third embodiment, fluorine may alternatively be ion-implanted at implantation energy of about 5 keV to about 30 keV and an implantation dosage of about 1.5×10¹⁵ cm⁻² to about 5.0×15 cm⁻².

While the silicon nitride film 47 (see FIG. 42) is entirely removed in the salicide process as shown in FIG. 43 in the aforementioned third embodiment, the silicon nitride film 47 may alternatively be partially left in regions requiring no formation of silicide films. In this case, a silicon oxide film is formed on the overall surface by CVD after removing the resist film 58b shown in FIG. 42. This silicon oxide film is so patterned by photolithography and wet etching as to leave multilayer films of the silicon nitride film 47 and the silicon oxide film on the regions requiring no formation of silicide films. Thus, no silicide films can be formed on the portions provided with the multilayer films of the silicon nitride film 47 and the silicon oxide film in the salicide step. In other words, the silicon nitride film 47 may be entirely removed as shown in FIG. 42, or may alternatively be entirely left in partial regions (not shown).

While the ion-implanted impurities are activated by heat treatment by RTA in each of the aforementioned first to fourth embodiments, the present invention is not restricted to this but the impurities may alternatively be activated by furnace annealing. In this case, the activation step is carried out under conditions of a heating temperature of about 700° C. to about 900° C. and a treatment temperature of about 30 minutes to about 60 minutes, for example.

While dangling bonds in the channel region 61b are terminated with fluorine in the aforementioned fourth embodiment, the present invention is not restricted to this but dangling bonds may alternatively be terminated with a halogenic element other than fluorine.

While fluorine is ion-implanted at the implantation energy of about 20 keV and the implantation rate of about 3×10¹⁵ cm⁻² in the aforementioned fourth embodiment, the present invention is not restricted to this but fluorine may alternatively be ion-implanted at implantation energy of about 10 keV to about 20 keV and an implantation dosage of about 1.5×10¹⁵ cm⁻² to about 5.0×10¹⁵ cm⁻².

While the source/drain regions 5, 25, 45 and 55 or 65 and 75 are constituted of the low-concentration impurity regions 5a, 25a and 35a, 45a and 55a or 65a and 75a and the high-concentration impurity regions 5b, 25b and 35b, 45b and 55b or 65b and 75b in each of the aforementioned embodiments, the present invention is not restricted to this but is also applicable to source/drain regions having no low-concentration impurity regions.

While fluorine is introduced into the regions extending over the junction interfaces between the semiconductor substrate 1, 21, 41 or 61 (well regions 14a, 14b, 52a and 52b or 73 and 74) and the source/drain regions 5, 25, 45 and 55 or 65 and 75, the side wall insulator films 7, 27, 46 or 66, the interface between the gate insulator film and the channel region(s) 1a, 21a, 41a and 41b or 61a and 61b and the gate insulator film(s) 3, 23, 43 or 63 in each of the aforementioned first to fourth embodiments, the present invention is not restricted to this but fluorine may alternatively be introduced into all of the regions extending over the junction interfaces between the semiconductor substrate 1, 21, 41 or 61 (well regions 14a, 14b, 52a and 52b or 73 and 74) and the source/drain regions 5, 25, 45 and 55 or 65 and 75, the side wall insulator films 7, 27, 46 or 66, the interface between the gate insulator film and the channel region(s) 1a, 21a, 41a and 41b or 61a and 61b and the gate insulator film(s) 3, 23, 43 or 63. Further alternatively, fluorine may be introduced into either two of the regions extending over the junction interfaces between the semiconductor substrate 1, 21, 41 or 61 (well regions 14a, 14b, 52a and 52b or 73 and 74) and the source/drain regions 5, 25, 45 and 55 or 65 and 75, the side wall insulator films 7, 27, 46 or 66, the channel region(s) 1a, 21a, 41a and 41b or 61a and 61b and the gate insulator film(s) 3, 23, 43 or 63. Further alternatively, either fluorine or carbon may be introduced into both of the regions extending over the junction interfaces between the semiconductor substrate 1, 21, 41 or 61 (well regions 14a, 14b, 52a and 52b or 73 and 74) and the source/drain regions 5, 25, 45 and 55 or 65 and 75 and the side wall insulator films 7, 27, 46 or 66.

1-17. (canceled)

18. A method of fabricating a semiconductor device, comprising steps of:
forming second conductivity type source/drain regions on the main surface of a first conductivity type semiconductor region to hold a channel region therebetween at a prescribed interval;
forming a gate electrode on said channel region through a gate insulator film;
forming side wall insulator films on the side surfaces of said gate electrode; and
introducing fluorine into at least any of regions extending over the junction interfaces between said first conductivity type semiconductor region and said second conductivity type source/drain regions, at least the interface between the gate insulator film and the central region of said channel region as well as said gate insulator film, and said side wall insulator films, wherein
said step of introducing fluorine includes a step of ion-implanting fluorine into said at least any regions extending over the junction interfaces between said first conductivity type semiconductor region and said second conductivity type source/drain regions at an implantation dosage of at least about 1.5×10¹⁵ cm⁻² and not more than about 3×10¹⁵ cm⁻².

19. The method of fabricating a semiconductor device according to claim 18, wherein
said step of introducing fluorine includes a step of ion-implanting said fluorine into said gate electrode and thereafter performing heat treatment thereby diffusing said fluorine from said gate electrode into said side wall insulator films while diffusing said fluorine from said gate electrode into said gate insulator film and at least the interface between the gate insulator film and the central region of said channel region.

20. The method of fabricating a semiconductor device according to claim 18, wherein
said step of introducing fluorine includes a step of ion-implanting said fluorine into said regions extending over the junction interfaces between said first conductivity type semiconductor region and said second conductivity type source/drain regions.

21. A method of fabricating a semiconductor device, comprising steps of:
forming a second conductivity type impurity region on the main surface of a first conductivity type semiconductor region; and
introducing an element of at least either fluorine or carbon into a region extending over the junction interface between said second conductivity type impurity region and said first conductivity type semiconductor region.

22. The method of fabricating a semiconductor device according to claim 21, wherein
said step of forming said second conductivity type impurity region includes a step of forming a second conductivity type source/drain region including a low-concentration impurity region and a high-concentration impurity region, and
said step of introducing said element of at least either fluorine or carbon includes a step of introducing said element of at least either fluorine or carbon into at least a region extending over the junction interface between said first conductivity type semiconductor region and said high-concentration impurity region.

23. The method of fabricating a semiconductor device according to claim 21, wherein
said step of introducing said element of at least either fluorine or carbon includes a step of ion-implanting fluorine into said region extending over the junction interface between said second conductivity type impurity region and said first conductivity type semiconductor region at an implantation dosage of at least about 1.5×10¹⁵ cm⁻² and not more than about 3×10¹⁵ cm⁻².

24. A method of fabricating a semiconductor device, comprising steps of:
forming a gate electrode on the surface of a first conductivity type semiconductor region through a gate insulator film;
ion-implanting an element reducing the dielectric constant at least into said gate electrode;
forming side wall insulator films on the side surfaces of said gate electrode;
forming a silicon nitride film at least on said side wall insulator films; and
diffusing said element reducing the dielectric constant from said gate electrode into said side wall insulator films by heat treatment;
ion-implanting a halogenic element into said gate electrode; and
diffusing said halogenic element in said gate electrode into said gate insulator film and the interface between said gate insulator film and said first conductivity type semiconductor region by heat-treating said first conductivity type semiconductor region, wherein
said step of ion-implanting said halogenic element includes a step of ion-implanting said fluorine at an implantation dosage of at least about 1.5×10¹⁵ cm⁻² and not more than about 5×10¹⁵ cm⁻².

25. The method of fabricating a semiconductor device according to claim 24, wherein
said step of ion-implanting said element reducing the dielectric constant includes a step of implanting said element reducing the dielectric constant also into said first conductivity type semiconductor region, and
said step of diffusing said element reducing the dielectric constant from said gate electrode into said side wall insulator films includes a step of diffusing said element reducing the dielectric constant from said first conductivity type semiconductor region into said side wall insulator films by heat treatment.

26. A method of fabricating a semiconductor device, comprising steps of:
forming a gate electrode on the main surface of a silicon substrate through a gate insulator film;
ion-implanting a halogenic element into said gate electrode; and
diffusing said halogenic element in said gate electrode into said gate insulator film and the interface between said gate insulator film and said silicon substrate by heat-treating said silicon substrate.

27. The method of fabricating a semiconductor device according to claim 26, wherein
said halogenic element is fluorine.

28. The method of fabricating a semiconductor device according to claim 26, wherein
said step of ion-implanting said halogenic element includes a step of ion-implanting said fluorine at an implantation dosage of at least about 1.5×10¹⁵ cm⁻² and not more than about 5×10¹⁵ cm⁻².

29. The method of fabricating a semiconductor device according to claim 26, wherein
said heat treatment for diffusing said halogenic element is performed only once after ion implantation of said halogenic element.

30. A method of fabricating a semiconductor device, comprising steps of:
forming a gate electrode on the main surface of a first conductivity type silicon substrate through a gate insulator film;
forming a pair of second conductivity type source/drain regions on the main surface of said silicon substrate to hold a channel region therebetween;
ion-implanting a halogenic element into said source/drain regions and said gate electrode; and
diffusing said halogenic element in said gate electrode into said gate insulator film and said channel region located on the interface between said gate insulator film and said silicon substrate while diffusing said halogenic element in said source/drain regions into said channel region located under said gate insulator film by heat-treating said silicon substrate; and
diffusing said halogenic element in said gate electrode into said gate insulator film and the interface between said gate insulator film and said silicon substrate by heat-treating said silicon substrate, wherein
said step of ion-implanting said halogenic element includes a step of ion-implanting said fluorine at an implantation dosage of at least about 1.5×10¹⁵ cm⁻² and not more than about 5×10¹⁵ cm⁻².
